(19) United States
(12) Patent Application Publication
(10) Pub. No.: US 2025/0357915 A1
(43) Pub. Date: Nov. 20, 2025

(54) PERFORMANCE IMPROVEMENT OF SAW RESONATOR BY SELECTIVELY CHANGING AMOUNT OF MATERIALS

(71) Applicant: Qorvo US, Inc., Greensboro, NC (US)

(72) Inventors: Patrik Rath, Munich (DE); Shogo Inoue, Longwood, FL (US); Marc Solal, Longwood, FL (US)

(21) Appl. No.: 19/202,462

(22) Filed: May 8, 2025

Related U.S. Application Data
(60) Provisional application No. 63/647,912, filed on May 15, 2024.

(51) Int. Cl. H03H 9/25; H03H 9/145

(52) U.S. Cl. CPC H03H 9/25; H03H 9/14552; H03H 9/64

(57) ABSTRACT

The present disclosure relates to a surface acoustic wave (SAW) resonator that includes at least a piezoelectric structure and an interdigital transducer (IDT) that is over the piezoelectric structure and features at least one edge region. The IDT includes multiple first electrode fingers and multiple second electrode fingers extending in a transverse direction. The first electrode fingers and the second electrode fingers are interleaved with one another along a longitudinal direction orthogonal to the transverse direction. The at least one edge region extends in the longitudinal direction and spans across certain ones of the first electrode fingers and certain ones of the second electrode fingers. Herein, an acoustic wave propagates in the at least one edge region at a different velocity than other regions confined in the IDT. The at least one edge region is realized in the IDT at least by a thickness variation of the piezoelectric structure.

### RELATED APPLICATIONS

This application claims the benefit of provisional patent application Ser. No. 63/647,912, filed May 15, 2024, the disclosure of which is hereby incorporated herein by reference in its entirety.

### FIELD OF THE DISCLOSURE

The present disclosure relates to a surface acoustic wave (SAW) resonator, in particular to a SAW resonator in which one or more materials are selectively removed and/or added for performance improvement.

### BACKGROUND

Acoustic wave devices are widely used in modern electronics. At a high level, an acoustic wave device often includes a piezoelectric material in contact with one or more electrodes. Piezoelectric materials acquire a charge when compressed, twisted, or distorted, and similarly compress, twist, or distort when a charge is applied to them. Accordingly, when an alternating electrical signal is applied to the one or more electrodes in contact with the piezoelectric material, a corresponding mechanical signal (i.e., an oscillation or vibration) is transduced therein. Based on the characteristics of the one or more electrodes on the piezoelectric material, the properties of the piezoelectric material, and other factors such as the shape of the acoustic wave device and other structures provided on the device, the mechanical signal transduced in the piezoelectric material exhibits a frequency dependence on the alternating electrical signal. Acoustic wave devices leverage this frequency dependence to provide one or more functions.

Exemplary acoustic wave devices include surface acoustic wave (SAW) resonators and bulk acoustic wave (BAW) resonators, which are increasingly used to form filters used in the transmission and reception of radio frequency (RF) signals for communication. Due to the stringent demands placed on filters for modern RF communications systems, acoustic wave devices for these applications are desired to provide a high-quality factor and wide bandwidth (i.e., high electromechanical coupling coefficient), and be small in size.

Often, undesired oscillations or vibrations are transduced in the piezoelectric material of an acoustic wave device which degrades the performance thereof. These undesired oscillations or vibrations are often referred to as spurious modes, such as transverse modes. For SAW filters, the transverse modes in the passband can lead to ripples and lead to failure under power.

To suppress the transverse modes, a piston mode and/or apodization technique may be used. The piston mode can suppress the transverse modes significantly; however, the existing configurations of the piston mode will result in an increased loss and a relatively low-quality factor. On the other hand, the sole apodization technique may maintain an acceptable quality factor but cannot sufficiently suppress the transverse modes.

In light of the above, there is a present need for improved acoustic wave resonator designs to achieve desired features of both quality factor and suppressed transverse modes. Further, there is also a need to keep the final product size competitive.

### SUMMARY

The present disclosure relates to a surface acoustic wave (SAW) resonator in which one or more materials are selectively removed and/or added for performance improvement. The disclosed SAW resonator includes a piezoelectric structure, an interdigital transducer (IDT) with at least one edge region, and a passivation structure. The IDT resides over the piezoelectric structure, such that portions of the piezoelectric structure are exposed through the IDT. The passivation structure at least partially covers the IDT and the exposed surfaces of the piezoelectric structure. Herein, the IDT includes a number of first electrode fingers and a number of second electrode fingers extending in a transverse direction. The first electrode fingers and the second electrode fingers are interleaved with one another along a longitudinal direction orthogonal to the transverse direction. The at least one edge region extends in the longitudinal direction and spans across certain ones of the first electrode fingers and certain ones of the second electrode fingers. An acoustic wave propagates in the at least one edge region at a different velocity than other regions confined in the IDT. The at least one edge region is realized in the IDT by at least one thickness variation of both a thickness variation of the piezoelectric structure and a thickness variation of the passivation structure.

According to one embodiment, a SAW resonator includes a piezoelectric structure and an IDT that resides over the piezoelectric structure and has at least one edge region. Herein, the IDT includes a number of first electrode fingers and a number of second electrode fingers extending in a transverse direction. The first electrode fingers and the second electrode fingers are interleaved with one another along a longitudinal direction orthogonal to the transverse direction. The at least one edge region extends in the longitudinal direction and spans across certain ones of the first electrode fingers and certain ones of the second electrode fingers. An acoustic wave propagates in the at least one edge region at a different velocity than other regions confined in the IDT. The at least one edge region is realized in the IDT at least by a thickness variation of the piezoelectric structure.

According to one embodiment, a method of implementing a SAW resonator starts with providing an initial SAW precursor including a piezoelectric structure. Next, an IDT is formed over the piezoelectric structure, such that portions of the piezoelectric structure are exposed through the IDT. Herein, the IDT includes a number of first electrode fingers and a number of second electrode fingers extending in a transverse direction. The first electrode fingers and the second electrode fingers are interleaved with one another along a longitudinal direction orthogonal to the transverse direction. After the IDT is formed, a passivation structure is formed at least partially covering the IDT and the exposed surfaces of the piezoelectric structure. An edge region is realized in the IDT, in which an acoustic wave propagates at a different velocity than other regions confined in the IDT. The edge region extends in the longitudinal direction and spans across certain ones of the first electrode fingers and certain ones of the second electrode fingers. The edge region is realized by modifying at least one of the piezoelectric structure and the passivation structure to achieve at least one of a thickness variation of the piezoelectric structure and a thickness variation of the passivation structure.

According to one embodiment, a method of implementing a SAW resonator starts with providing an initial SAW precursor including a piezoelectric structure. Next, the piezoelectric structure is modified to achieve a thickness variation of the piezoelectric structure. An IDT is then formed over the piezoelectric structure, such that portions of the piezoelectric structure are exposed through the IDT. Herein, the IDT includes a number of first electrode fingers and a number of second electrode fingers extending in a transverse direction. The first electrode fingers and the second electrode fingers are interleaved with one another along a longitudinal direction orthogonal to the transverse direction. An edge region is realized in the IDT at least due to the thickness variation of the piezoelectric structure. An acoustic wave propagates at a different velocity in the edge region than other regions confined in the IDT. The edge region extends in the longitudinal direction and spans across certain ones of the first electrode fingers and certain ones of the second electrode fingers.

According to one embodiment, a system includes radio-frequency (RF) input circuitry, RF output circuitry, and filter circuitry, which includes at least one SAW resonator, connected between the RF input circuitry and the RF output circuitry. The at least one SAW resonator includes a piezoelectric structure, an IDT with at least one edge region, and a passivation structure. The IDT resides over the piezoelectric structure, such that portions of the piezoelectric structure are exposed through the IDT. The passivation structure at least partially covers the IDT and the exposed surfaces of the piezoelectric structure. Herein, the IDT includes a number of first electrode fingers and a number of second electrode fingers extending in a transverse direction. The first electrode fingers and the second electrode fingers are interleaved with one another along a longitudinal direction orthogonal to the transverse direction. The at least one edge region extends in the longitudinal direction and spans across certain ones of the first electrode fingers and certain ones of the second electrode fingers. An acoustic wave propagates in the at least one edge region at a different velocity than other regions confined in the IDT. The at least one edge region is realized in the IDT by at least one thickness variation of both a thickness variation of the piezoelectric structure and a thickness variation of the passivation structure.

According to one embodiment, a system includes radio-frequency (RF) input circuitry, RF output circuitry, and filter circuitry, which includes at least one SAW resonator, connected between the RF input circuitry and the RF output circuitry. The at least one SAW resonator includes a piezoelectric structure and an IDT that resides over the piezoelectric structure and has at least one edge region. Herein, the IDT includes a number of first electrode fingers and a number of second electrode fingers extending in a transverse direction. The first electrode fingers and the second electrode fingers are interleaved with one another along a longitudinal direction orthogonal to the transverse direction. The at least one edge region extends in the longitudinal direction and spans across certain ones of the first electrode fingers and certain ones of the second electrode fingers. An acoustic wave propagates in the at least one edge region at a different velocity than other regions confined in the IDT. The at least one edge region is realized in the IDT at least by a thickness variation of the piezoelectric structure.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a three-dimensional (3D) view of a representative surface acoustic wave (SAW) resonator.

FIG. 2 illustrates a top view of an exemplary SAW resonator according to embodiments of the present disclosure.

FIGS. 3A-16 illustrate different configurations of a piezoelectric structure of the SAW resonator to achieve thickness variations according to embodiments of the present disclosure.

FIGS. 17A-17D illustrate several configurations of a representative passivation structure applied in the SAW resonator.

FIGS. 18-24C illustrate different configurations of a passivation structure of the SAW resonator to achieve thickness variations according to embodiments of the present disclosure.

FIGS. 25A-25D illustrate an exemplary combination of the piezoelectric structure and the passivation structure to achieve thickness variations according to embodiments of the present disclosure.

FIG. 26 illustrates a flowchart of an exemplary method of providing the SAW resonator according to some embodiments of the present disclosure.

FIG. 27 illustrates a block diagram of an example system that includes at least one SAW filter which is implemented by one or more SAW resonators.

FIG. 28 illustrates a block diagram of an exemplary communication device that includes at least one SAW filter which is implemented by one or more SAW resonators.

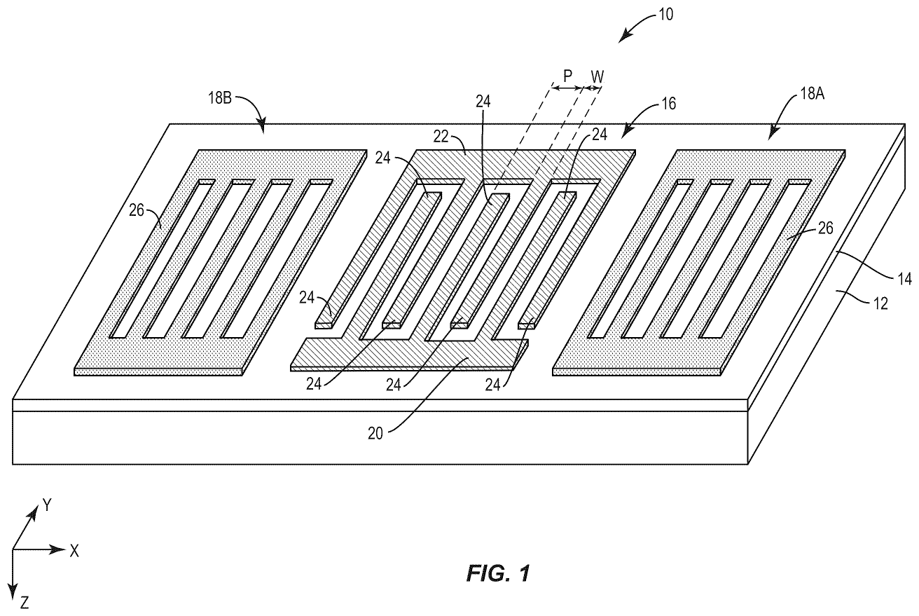

It will be understood that for clarity of illustration, FIGS. 1-28 may not be drawn to scale.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

FIG. 1 illustrates a three-dimensional view of a representative surface acoustic wave (SAW) resonator 10. The SAW resonator 10 includes a substrate 12, a piezoelectric layer 14 on the substrate 12, an interdigital transducer (IDT) 16 on a surface of the piezoelectric layer 14 opposite the substrate 12, and two reflectors 18A and 18B on the surface of the piezoelectric layer 14 placed at opposite sides of the IDT 16. While not shown to avoid obscuring the drawings, additional passivation layers, frequency trimming layers, or any other layers may be provided over all or portions of the exposed surfaces of the piezoelectric layer 14, the IDT 16, and the two reflectors 18A and 18B, or provided vertically between the substrate 12 and the piezoelectric layer 14.

The IDT 16 includes a first electrode 20 and a second electrode 22, each of which may include one or more electrode fingers 24 that are interleaved with one another as shown. The first electrode 20 and the second electrode 22 may also be referred to as comb electrodes. A lateral distance between adjacent electrode fingers 24 of the first electrode 20 and the second electrode 22 defines an electrode pitch P of the IDT 16. The electrode pitch P may at least partially define a center frequency wavelength λ of the SAW resonator 10, where the center frequency is the primary frequency of mechanical waves generated in the piezoelectric layer 14 by the IDT 16. A finger width W of the adjacent electrode fingers 24 over the electrode pitch P may define a duty factor of the IDT 16, which may dictate certain operating characteristics of the SAW resonator 10.

In operation, an alternating electrical input signal provided at the first electrode 20 is transduced into a mechanical signal in the piezoelectric layer 14, resulting in one or more acoustic waves therein. In the case of the SAW resonator 10, the resulting acoustic waves are predominately surface acoustic waves. As discussed above, due to the electrode pitch P and the duty factor of the IDT 16, the characteristics of the material of the piezoelectric layer 14, and other factors, the magnitude and frequency of the acoustic waves transduced in the piezoelectric layer 14 are dependent on the frequency of the alternating electrical input signal. This frequency dependence is often described in terms of changes in the impedance and/or a phase shift between the first electrode 20 and the second electrode 22 with respect to the frequency of the alternating electrical input signal. An alternating electrical potential between the two electrodes 20 and 22 creates an electrical field in the piezoelectric material which generates acoustic waves. The acoustic waves travel at the surface and are eventually transferred back into an electrical signal between the electrodes 20 and 22. The two reflectors 18A and 18B reflect the acoustic waves in the piezoelectric layer 14 back towards the IDT 16 to confine the acoustic waves in the area surrounding the IDT 16. Each reflector 18A or 18B may include one or more reflective fingers 26 (only two reflective fingers are labeled with a reference number for clarity). The IDT 16 and the two reflectors 18A and 18B may be formed of metal.

Existing SAW resonators, such as the SAW resonator 10, may have unwanted spurious modes (e.g., transverse modes), which can hinder practical use of the SAW resonator as a sole resonator or as a component of a filter. To suppress the transverse mode effect on the response, a piston mode and/or apodization technique may be used. The piston mode is configured to change the velocity of acoustic waves across apertures within the IDT (i.e., provides fast/slow regions transversely across the IDT along a y direction) so as to suppress the transverse modes. One existing way to achieve the fast/slow regions is to change the duty factor in a certain region of the IDT by adding metal mass to the electrode fingers, which can be called a hammer head region (see U.S. Pat. No. 7,939,989 B2). For a non-limiting example, within a hammer head region, the IDT duty factor is 65% (realizing a slow region), while within the remaining IDT regions, the IDT duty factor is 50% (realizing a fast region). Although the existing configuration of the piston mode can suppress the transverse modes significantly and achieve a desirably high electromechanical coupling coefficient k², the existing configuration will result in an increased loss and a relatively low-quality factor due to the increased metal mass of the IDT. In addition, the existing configuration of the piston mode leads to reduced metal-electrode gaps, which poses risks to manufacturability and power failures (e.g., electrostatic discharge, ESD, failures). Furthermore, for large IDT duty factor applications, the hammer head approach may not provide enough velocity contrast, and consequently may not achieve clear fast/slow regions. On the other hand, the apodization technique is configured to create an apodization shape (e.g., a shape of a mathematical function) in the IDT, especially across the electrode fingers in an x direction. Although the apodization technique may maintain an acceptable quality factor, the apodization technique cannot sufficiently suppress the transverse modes by itself. The piston mode may be combined with the apodization technique to achieve a trapezoidal mode, which can take advantage of all features of the piston mode and the apodization technique.

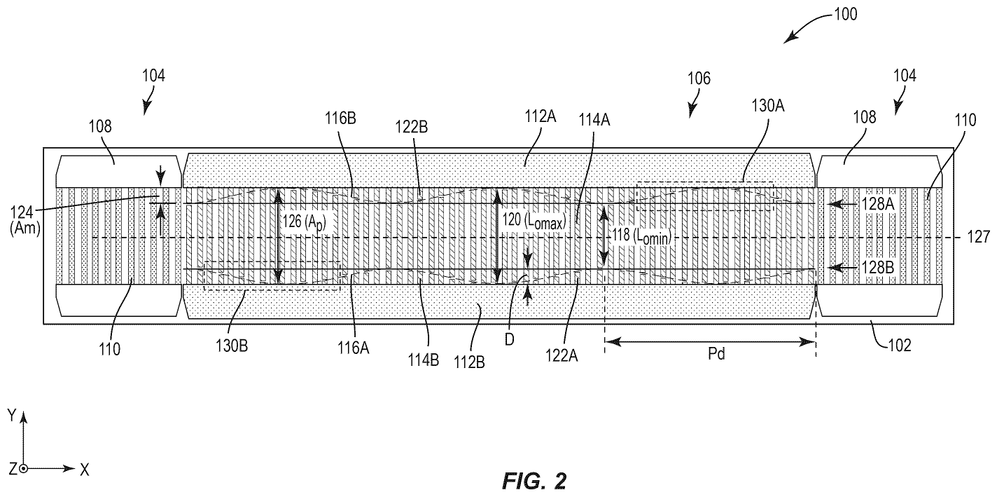

The present disclosure describes a SAW resonator that achieves regions of different resonance velocities in a transverse direction (i.e., the piston mode along the y direction) to suppress the transverse mode without sacrificing the quality factor/loss and still maintaining a high electromechanical coupling coefficient k². In addition, the disclosed SAW resonator may also utilize the apodization technique. FIG. 2 illustrates a top view of an exemplary SAW resonator 100 according to embodiments of the present disclosure. The SAW resonator 100 may include a piezoelectric structure 102, a pair of reflectors 104 over the piezoelectric structure 102, and an IDT 106 over the piezoelectric structure 102 and positioned between the reflectors 104. As such, portions of the piezoelectric structure 102 are exposed through the IDT 106 and the reflectors 104.

In detail, each reflector 104 may include a pair of reflector busbars 108 each extending in the x-direction (e.g., the longitudinal direction) and a number of reflector bars 110 extending between the pair of reflector busbars 108 in the y-direction (e.g., the transverse direction, orthogonal to the longitudinal direction). The IDT 106 may include a first busbar 112A and a second busbar 112B each extending in the x-direction. The IDT 106 also includes a number of first electrode fingers 114A extending in the y-direction from the first busbar 112A, and a number of second electrode fingers 114B extending in the y-direction from the first busbar 112B. The first electrode fingers 114A and the second electrode fingers 114B are interleaved with one another along the x direction.

Herein, the IDT 106 may be apodized with one or more apodization edges 116 (e.g., a first apodization edge 116A, and a second apodization edge 116B), each of which is part of a curve that follows a regular pattern (e.g., a sine wave) with a period between 2 and 50 lambdas and/or a random pattern. An acoustic wave, having a wavelength of λ, may propagate in the first and second electrode fingers 114A and 114B along the x-direction. Each first electrode finger 114A may extend from the first busbar 112A to the first apodization edge 116A, and each second electrode finger 110B may extend from the second busbar 112B to the second apodization edge 116B. In some embodiments, a distance between the centers of two adjacent first electrode fingers 114A (e.g., in the x-direction) may be λ, and a distance between the centers of two adjacent second electrode fingers 114B (e.g., in the x-direction) may be λ.

Each first electrode finger 114A may partially overlap with at least one adjacent second electrode finger 114B (e.g., or both adjacent second electrode fingers 114B) in the y-direction, and each second electrode finger 114B may partially overlap with at least one adjacent first electrode finger 114A (e.g., or both adjacent first electrode fingers 114A) in the y-direction. A minimum overlap 118 between one first electrode finger 114A and an adjacent second electrode finger 114B may be referred to as an “opening,” and may have a dimension (e.g., in the y-direction) of Lₒₘᵢₙ. In some embodiments, a maximum overlap 120 between one first electrode finger 114A and an adjacent second electrode finger 114B has a dimension (e.g., in the y-direction) of Lₒₘₐₓ and is normalized to be 1. Lₒₘᵢₙ is a ratio (e.g., normalized value) between the actual dimensions of the minimum overlap 118 and the actual dimension of the maximum overlap 120. For example, Lₒₘᵢₙ is a fraction between 0 and 1. In some embodiments, Lₒₘᵢₙ may be equal to or greater than zero such that there is a desirable overlap between one first electrode finger 114A and an adjacent second electrode finger 114B in the SAW resonator 100. In some embodiments, Lₒₘᵢₙ is greater than 5% of Lₒₘₐₓ. In some embodiments, Lₒₘᵢₙ is greater than 10% of Lₒₘₐₓ. In some other embodiments, Lₒₘᵢₙ is greater than 15% of Lₒₘₐₓ and even in some other cases greater than 80% of Lₒₘₐₓ.

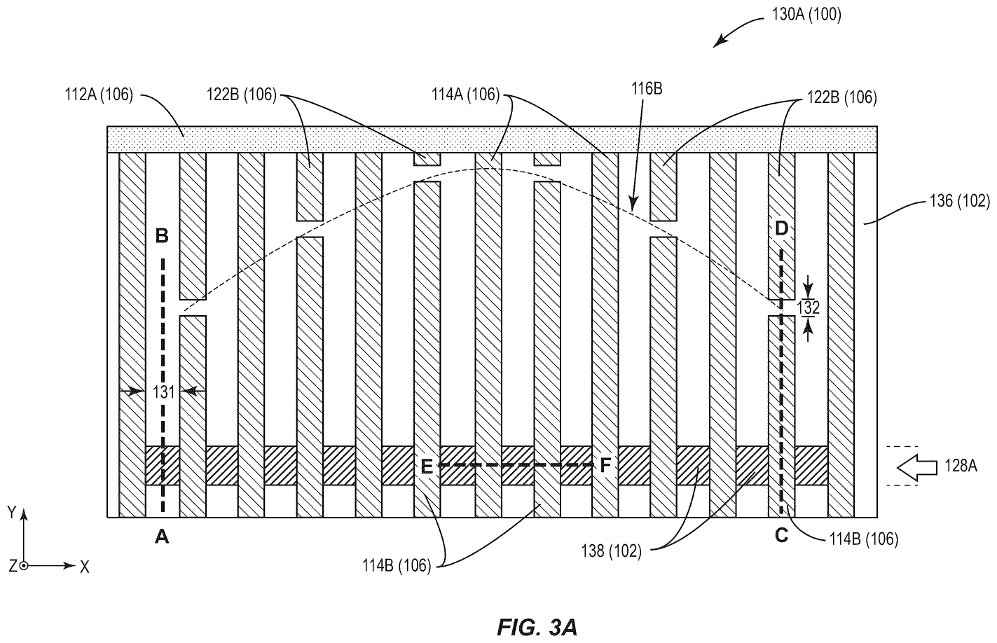

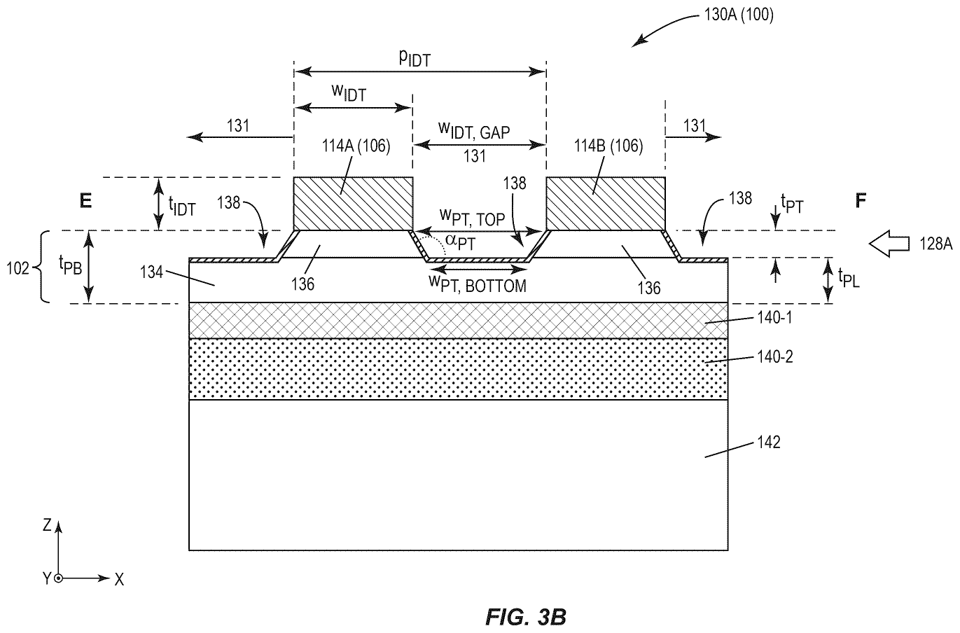

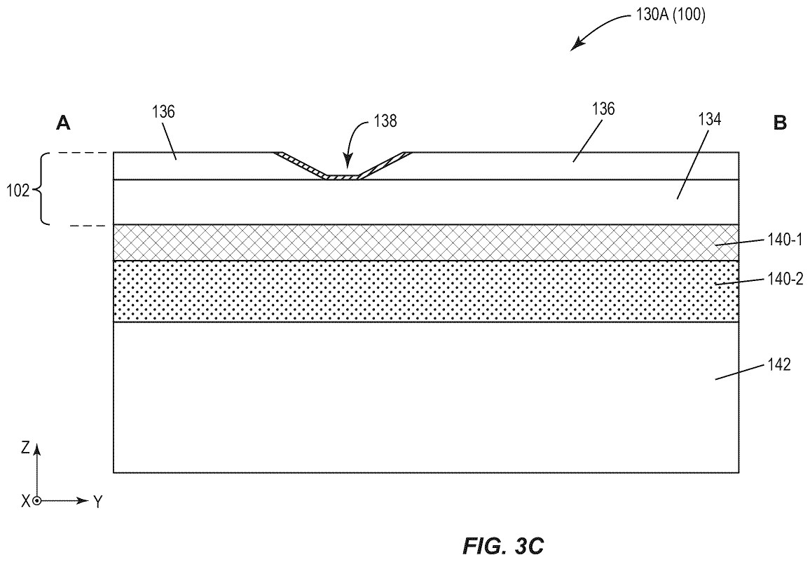

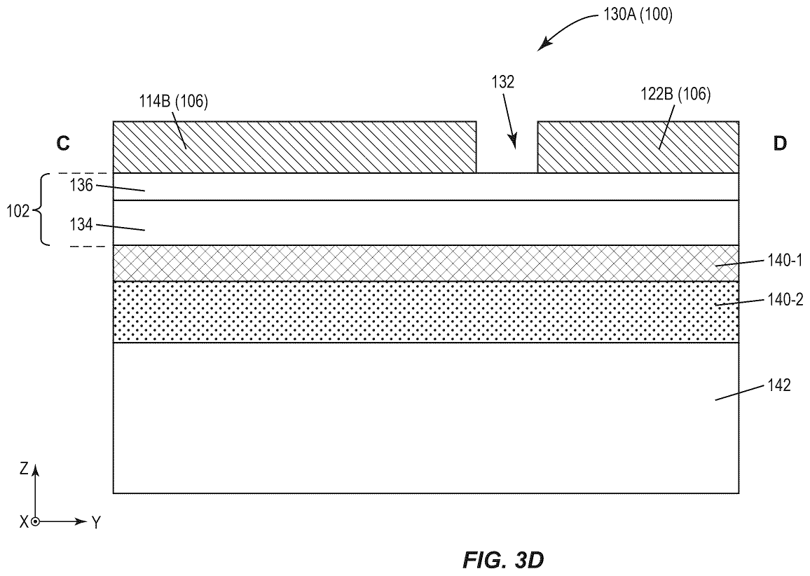

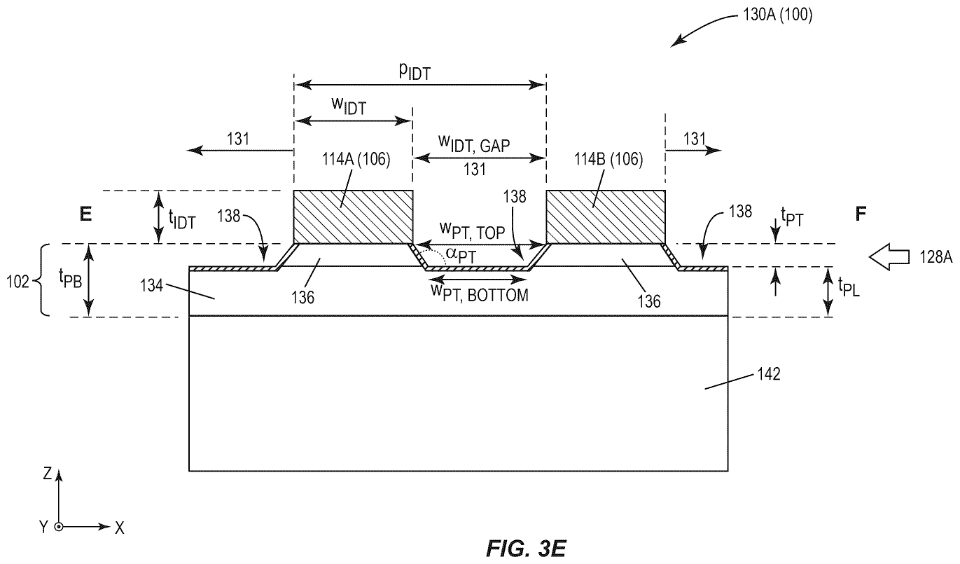

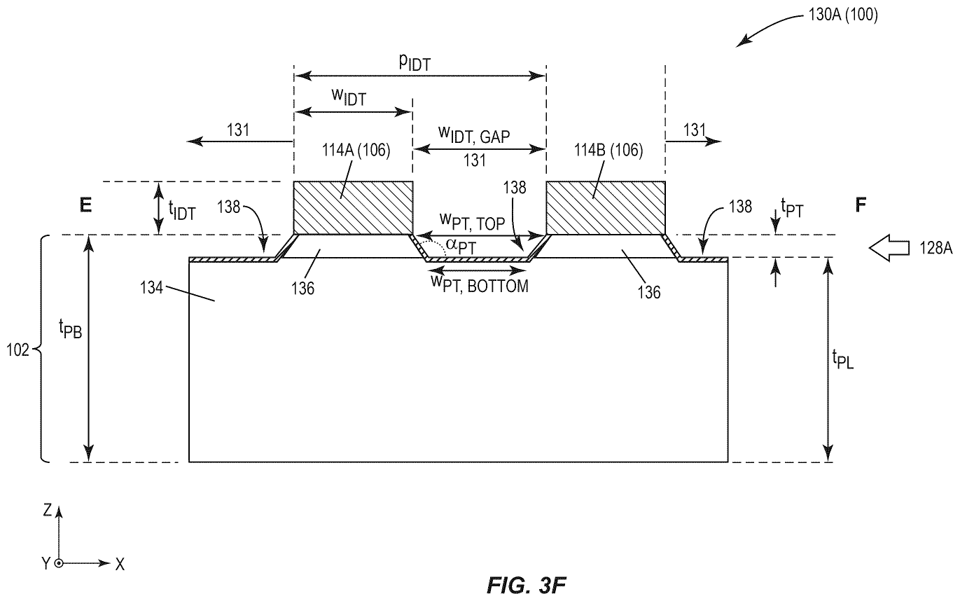

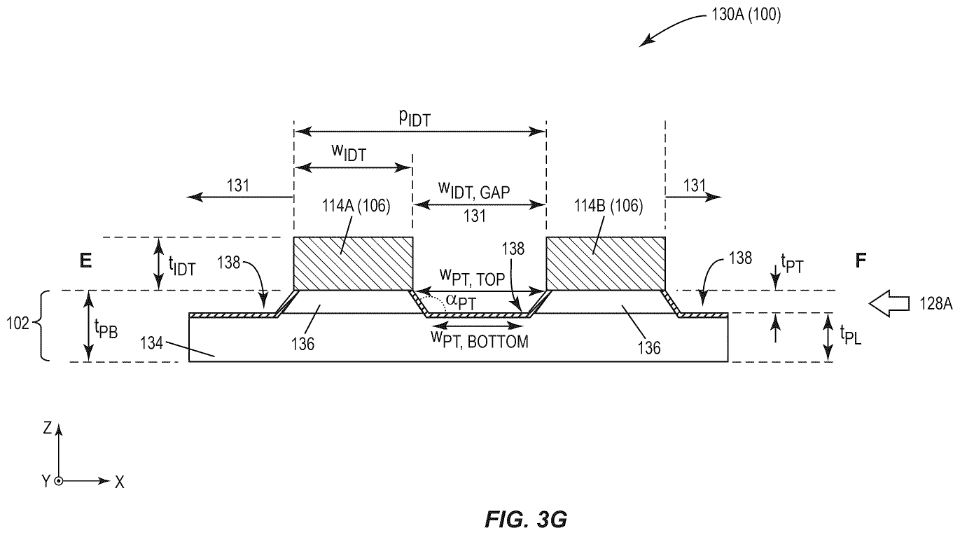

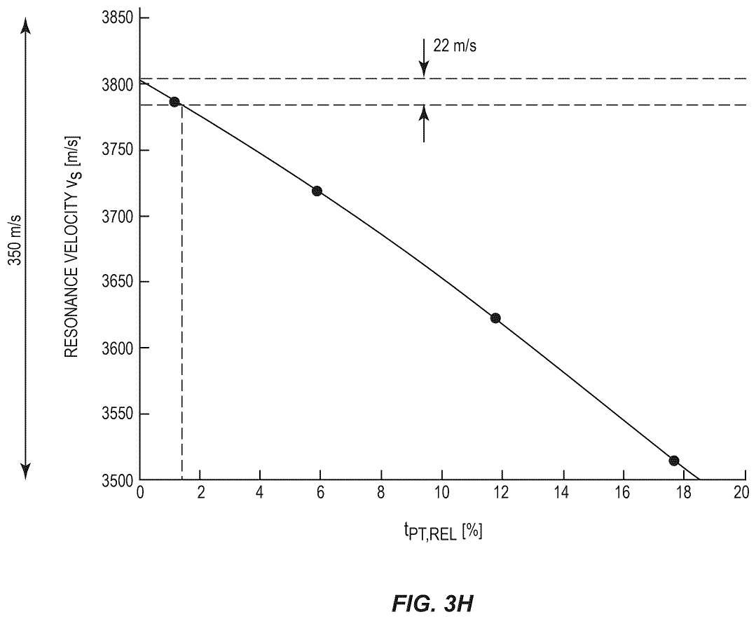

The IDT 106 may also include a number of first dummy electrodes 122A extending from the second busbar 112B in the y-direction, and a number of second dummy electrodes 122B extending from the first busbar 112A in the y-direction. Each first dummy electrode 122A may be positioned between two adjacent second electrode fingers 114B, and each second dummy electrode 122B may be positioned between two adjacent first electrode fingers 114A. Each first dummy electrode 122A may be aligned with a corresponding first electrode finger 114A in the y-direction, and a second dummy electrode 122B may be aligned with a corresponding second electrode finger 114B in the y-direction. A gap (e.g., a transverse gap 132 shown in FIGS. 3A and 3D) between one dummy electrode 122 and the corresponding electrode finger 114 may have a dimension that is greater than zero (more details are shown below).

The first apodization edge 116A and/or the second apodization edge 116B, across adjacent overlapping electrode fingers 114, are provided as part of a curve/pattern in the x-direction. The first apodization edge 116A and the second apodization edge 116B may be employed to confine the lengths of the electrode fingers 114 and the corresponding dummy electrodes 122, respectively, and thus define the apodization parameters of the IDT 106. For example, the first apodization edge 116A and the second apodization edge 116B may extend in periods with an amplitude to cause the lengths of the electrode fingers 114 and the dummy electrodes 122 to vary accordingly and periodically. In various embodiments, the apodization edge 116A and/or the second apodization edge 116B may include a repeated pattern or non-repeated pattern including a wave apodization, an arccosine apodization, a cosine/sine apodization, a modified arccosine apodization, a weighted dummy apodization, a slanted apodization, a saw-shaped apodization, a triangle-shaped apodization, a random apodization, an intermittent wave apodization, and/or any shape of apodization. In some embodiments, the number of periods of the apodization edge 116 may be at least 3. In some embodiments, the first apodization edge 116A and/or the second apodization edge 116B may include a period Pd, e.g., a full period, which may be part of a periodic curve or a random curve starting at a horizontal axis (parallel to the x-direction) and having both a peak about the horizontal axis and a trough below the horizontal axis. In one period Pd, the first apodization edge 116A and/or the second apodization edge 116B may have an amplitude 124 that is the distance between the highest peak and the lowest valley, and can be denoted as Am. In some embodiments, Am is between about 0.5λ and about 10λ. For example, Am may be 0.5λ, 1λ, 1.5λ, 2λ, 2.4λ, 2.6λ, 3λ, 3.5λ, 4λ, 5λ, 7λ, 7.5λ, 8λ, etc. An aperture 126 may be the largest distance between the first apodization edge 116A and the second apodization edge 116B in the y-direction. In some embodiments, the dimension of the aperture 126 may be Aₚ and may be between about 5) and about 25λ. For example, Aₚ may be 5λ, 5.5λ, 7λ, 8λ, 10λ, 12λ, 15λ, 18λ, 20λ, 21.5λ, 23.5λ, 24λ, 25λ, etc. When the first apodization edge 116A and the second apodization edge 116B are symmetric about a middle line 127, the maximum overlap 120 may be located between the peaks of the first apodization edge 116A and the second apodization edge 116B (e.g., at half period ½Pd). In some embodiments, the amplitude Am of the first apodization edge 116A/the second apodization edge 116B may be calculated as Am=Lₒₘₐₓ/2×(1−Lₒₘᵢₙ).

In some embodiments, a minimum length of one dummy electrode 122, in the y-direction, can be zero or non-zero, such as less than 2λ, less than λ, less than 0.5λ, less than 0.25λ, or 0. FIG. 2 illustrates the minimum length of one dummy electrode 122 being approximate to zero. A smaller minimum length of one dummy electrode 122 may result in a higher Q factor, a higher electromechanical coupling coefficient k², and improved transverse mode suppression. In some embodiments, the area formed by the dummy electrodes 122 extending from the same busbar 112 may be referred to as an inactive area, and the area in which the electrode fingers 114 overlap with one another may be referred to as an active area.

The IDT 106 includes one or more edge regions 128 (e.g., a first edge region 128A and a second edge region 128B), within which the acoustic wave may propagate at a different velocity (e.g., faster or slower) than other regions confined in the IDT 106 (e.g., a center region of the IDT 106 between the first edge region 128A and the second edge region 128B). Each edge region 128 in the IDT 106 typically extends in the x direction and spans across certain electrode fingers 114A/114B. The edge regions 128 may be realized in various ways. The structures/layers within the SAW resonator 100 may be transformed into various configurations (e.g., varying in x, y, z direction) to achieve the edge regions 128 in the IDT 106. The edge region(s) 128 may change/modify the SAW amplitude profile of the transverse mode and can be a slow region in which the acoustic wave travels at a lower velocity or a fast region in which the acoustic wave travels at a higher velocity than in the center region. The edge region(s) 128 may modify the mode profiles in the transverse direction and thus modify the transverse modes. In different applications, the first edge region 128A may be closer to the first busbar 112A than the second busbar 112B, and the second edge region 128B may be closer to the second busbar 112B than the first busbar 112A. A distance D from an edge of a busbar 112 to a center of the closest edge region 128 may be between about 0 and about ½Aₚ. In some embodiments, the first and second edge regions 128A and 128B are symmetric about the middle line 127 of the IDT 106 in the y direction. In some embodiments, a width (e.g., in the y-direction) of each edge region 128 may be greater than 0 and less than about 2λ. For example, the width of each edge region 128 may be less than 2λ, 1.5λ, 1.0λ, 0.75λ, 0.5λ, 0.25λ, 0.2λ, etc. In some embodiments, the edge regions 128 may each be located away from an outer region of the SAW resonator 100, such that the distance between the edge regions 128 and the closest outer region is greater than zero. In some embodiments, the edge regions 128 may each be located near the apodization edge 116. In some embodiments, the SAW resonator 100 may include fewer or more edge regions 128 with different configurations.

FIGS. 3A-3D illustrate enlarged views of a first edge portion 130A of the SAW resonator 100 with the first edge region 128 in FIG. 2 according to some embodiments. A second edge portion 130B of the SAW resonator 100 with the second edge region 128B may have a similar configuration as the first edge portion 130A and is not shown herein. FIG. 3A is a top view of the first edge portion 130A, while FIGS. 3B-3D are different cross-sectional views of the first edge portion 130A. FIG. 3B is a cross-sectional view along an E-F dashed line in a resonator's propagation direction (i.e., in the x direction), FIG. 3C is a cross-sectional view along an A-B dashed line (in the y direction) through an electrode width gap 131 (i.e. a gap between one first electrode finger 114A and an adjacent second electrode finger 114B), and FIG. 3D is a cross-sectional view along a C-D dashed line on the electrode finger 114 and its corresponding dummy electrode 122 (in the y direction). For clarity, only certain dummy electrodes and certain electrode fingers are labeled with reference numbers.

As illustrated in FIG. 3A, the second apodization edge 116B is employed to confine the lengths of the second electrode fingers 114 and the second dummy electrodes 122B, and thus define the apodization parameters of the IDT 106. A transverse gap 132 between one dummy electrode 122 (e.g., one second dummy electrode 122B) and the corresponding electrode finger 114 (e.g., the corresponding second electrode finger 114B) has a dimension greater than zero. The same concepts are applied to the first apodization edge 116A (not shown).

Herein, the first edge region 128A is realized in the IDT 106 by a thickness variation within the piezoelectric structure 102 to achieve regions of different velocities in the transverse direction (i.e., the y direction). The piezoelectric structure 102 includes a lower piezoelectric region 134 and an upper piezoelectric region 136 with a number of discrete piezoelectric trenches 138, which are confined within the first edge region 128A (details illustrated in FIG. 3B). Herein and hereafter, the pattern shading over the piezoelectric trenches 138 is used solely to clearly indicate locations of the piezoelectric trenches 138 and does not represent any additional material. The IDT 106 has a thickness tor (i.e., a thickness of each electrode finger 114A/114B). Each piezoelectric trench 138 has a depth t_{PT}, which is the same as a thickness of the upper piezoelectric region 136. The upper piezoelectric region 136 with the piezoelectric trenches 138 resides over the lower piezoelectric region 134 that typically has a uniform thickness t_{PL}. It is clear that a thickness of the piezoelectric structure 102 within the piezoelectric trenches 138 (i.e., only the thickness of the lower piezoelectric region 134) is thinner than a base thickness t_{PB} of any remaining portions of the piezoelectric structure 102 (i.e., a combination thickness of the thickness of the lower piezoelectric region 134 and the thickness of the upper piezoelectric region 136, t_{PB}=t_{PL}+t_{PT}). The first edge region 128A herein may achieve a slower region than other regions confined in the IDT 106.

In some embodiments, the piezoelectric structure 102 might be on top of one or more dielectric layers 140 (e.g., a first dielectric layer 140-1 and a second dielectric layer 140-2), which can be on top of a handle wafer 142 (e.g., a guided SAW resonator). The handle wafer 142 may be formed of an insulating material or a semiconductor material, such as silicon, sapphire, quartz, silicon carbide, or diamond, but is not limited thereto, and each dielectric layer 140 may be formed of a suitable dielectric material, such as silicon dioxide or silicon nitride, but is not limited thereto. The piezoelectric structure 102 may be formed of any suitable piezoelectric material(s), such as lithium tantalate (LT) or lithium niobate (LiNbO₃) but is not limited thereto. The base thickness t_{PB} of the piezoelectric structure 102 might be less than λ. In some embodiments, the piezoelectric structure 102 might be on top of the handle wafer 142 without the one or more dielectric layers 140 in between, as illustrated in FIG. 3E. In certain cases, the piezoelectric structure 102 is thick enough or rigid enough to function as a piezoelectric substrate. Accordingly, the handle wafer 142 and the one or more dielectric layers 140 may be omitted. FIG. 3F illustrates a bulk piezoelectric SAW resonator having a thick piezoelectric structure 102 without the handle wafer 142 and the dielectric layers 140, while FIG. 3G illustrates a membrane piezoelectric SAW resonator having a piezoelectric membrane 102 without the handle wafer 142 and the dielectric layers 140. In some embodiments, the piezoelectric structure 102 might be on top of a reflection structure, which includes alternating low acoustic impedance layers and high acoustic impedance layers in the z direction (i.e., a vertical direction), and the reflection structure is on top of the handle wafer 142 (e.g., SAW resonator with a Bragg mirror, not shown).

The electrode fingers 114A/114B might be formed of a stack of several metals and reside over the upper piezoelectric region 136. A lateral distance between corresponding sides of one first electrode finger 114A and an adjacent second electrode finger 114B defines an electrode pitch P_{IDT} of the IDT 106, which equals a finger width W_{IDT} of one electrode finger 114A/114B plus an electrode gap width W_{IDT,GAP} of the electrode width gap 131 (between facing sides of one first electrode finger 114A and the adjacent second electrode finger 114B). For a non-limiting example, the electrode fingers 114A/114B may have a uniform finger width W_{IDT}. No extra metal mass is added to the electrode fingers 114A/114B to change the finger width W_{IDT}. As such, there will be no potential loss due to the additional metal mass. In addition, a relatively large electrode gap width W_{IDT,GAP} will reduce the risk of shorting, ESD, and/or power failure.

Some parameters of the SAW resonator 100:

λ_{IDT}=2*P_{IDT}

DF_{IDT}=(W_{IDT}/P_{IDT})*100%

t_{PT,rel}=(t_{PT}/t_{PB})*100%

t_{PT,per lambda}=(t_{PT}/λ_{IDT})*100%

λ_{IDT} is a center frequency wavelength of the SAW resonator 100, DF_{IDT} is a duty factor of the IDT 106, t_{PT,rel} is a ratio between the depth of one piezoelectric trench 138 and the base thickness of the piezoelectric structure 102 in the z direction, and t_{PT,per lambda} is a ratio between the trench depth and the wavelength.

By utilizing the piezoelectric trench 138 in the piezoelectric structure 102, a large velocity reduction can be achieved in the edge region(s) 128. Removing only a small fraction of the piezo thickness (on the order of t_{PT,rel}=1˜2%) is often sufficient to achieve a noticeable velocity reduction, where t_{PT per lambda}=0.2˜ 0.7%. Deeper removal is also applicable. FIG. 3H illustrates a velocity variation versus the thickness ratio t_{PT,rel}. For a non-limiting example, t_{PT,rel}=1.5% (e.g., t_{PB}=500 nm and t_{PT}=7.5 nm) and can lead to a 22 meter/second velocity reduction. Larger depths of the piezoelectric trenches 138 for larger t_{PT,rel} will lead to larger velocity reduction. For a typical duty factor (e.g., DF_{IDT} is about 50%) and large duty factor applications (e.g., DF_{IDT}>55%, >60%, or even >65%), the utilization of the piezoelectric trench 138 can provide enough velocity contrast within the IDT 106 to sufficiently suppress spurious transverse modes in the resonator response.

In some embodiments, each piezoelectric trench 138 is located within the active area and between one first electrode finger 114A and an adjacent (in the x direction) second electrode finger 114B without overlapping with any electrode finger 114 (i.e., no portion of any electrode finger 114 extends over the piezoelectric trenches 138). For the purpose of this illustration, the piezoelectric trenches 138 may be aligned in the x direction (e.g., no shift in the y direction, shown in FIG. 3A). Each piezoelectric trench 138 has a one-step configuration and has a rectangular shape in x-y dimensions and approximately a trapezoidal shape in x-z/y-z dimensions (e.g., shown in FIGS. 3B and 3C). For the trapezoidal shape in the x-z/y-z dimensions, a top trench width W_{PT,top} may be equal to or smaller than the electrode gap width W_{IDT,gap}, and a bottom trench width W_{PT,bottom} may be smaller or larger than the top trench width W_{PT,top}. A trench sidewall angle α_{PT}, which is an angle between the bottom surface of one piezoelectric trench 138 and a sidewall of one piezoelectric trench 138, is typically larger than 90° but not limited to (e.g., may be smaller than) 90°. In different applications, the piezoelectric trenches 138 may have a shift in the y direction and may have any proper shape in the x-y/x-z/y-z dimensions. For a non-limiting example, each piezoelectric trench 138 may have any proper shape in the x-y/x-z/y-z dimensions, such as a circular shape, an oval shape, a parabolic shape, a rounded shape, a square shape, a rectangular shape, a parallelogram shape, a trapezoidal shape or a polygonal shape. In addition, one piezoelectric trench 138 may have a two-step or multiple-step configuration (e.g., an inverse multi-layer cake configuration). Furthermore, for multiple piezoelectric trenches 138, the piezoelectric trenches 138 may have different shapes and/or different depths (leading to different t_{PT,rel}). For the continuous piezoelectric trench 138, the piezoelectric trench 138 may have variations in shape and/or in depth.

Example configurations of how the piezoelectric trenches 138 can be combined with the electrode fingers 114 are shown in FIGS. 3A-16. These configuration examples highlight how to build a trapezoidal mode as well as a piston mode without apodization in the IDT 106. In addition, the SAW resonator 100 can be described as a guided SAW resonator. The concepts of this disclosure are not limited to a guided SAW configuration, and other resonator options are possible. For simplicity, the following figures/descriptions use guided SAW resonators as examples.

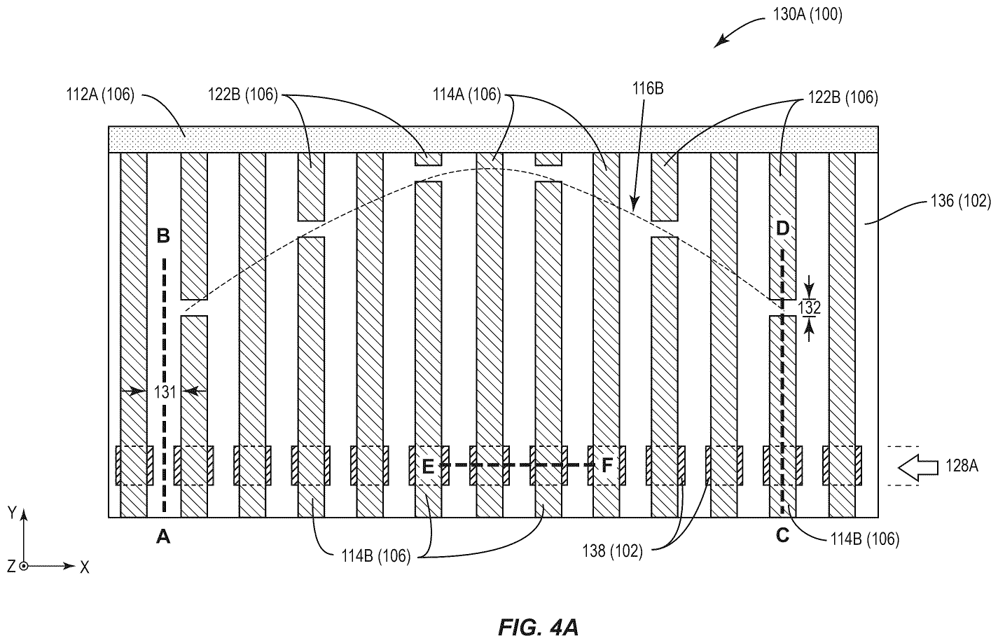

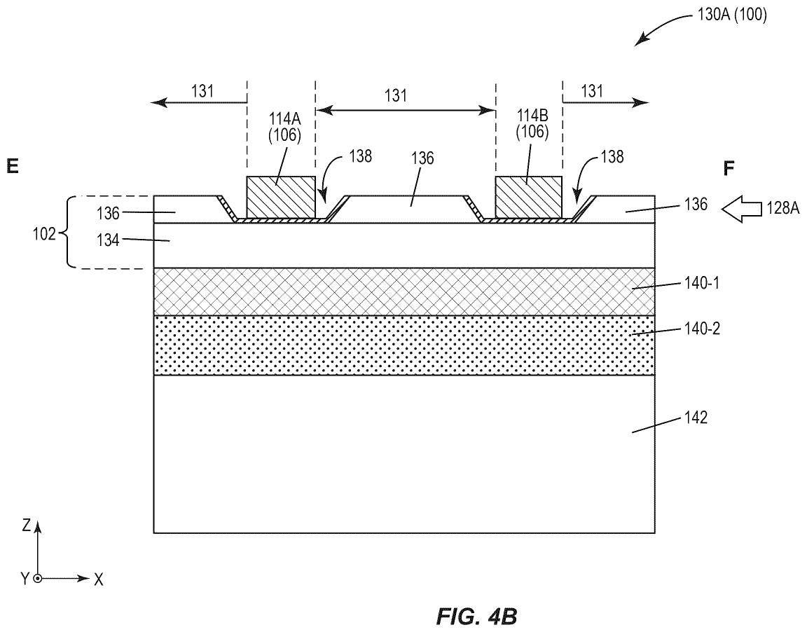

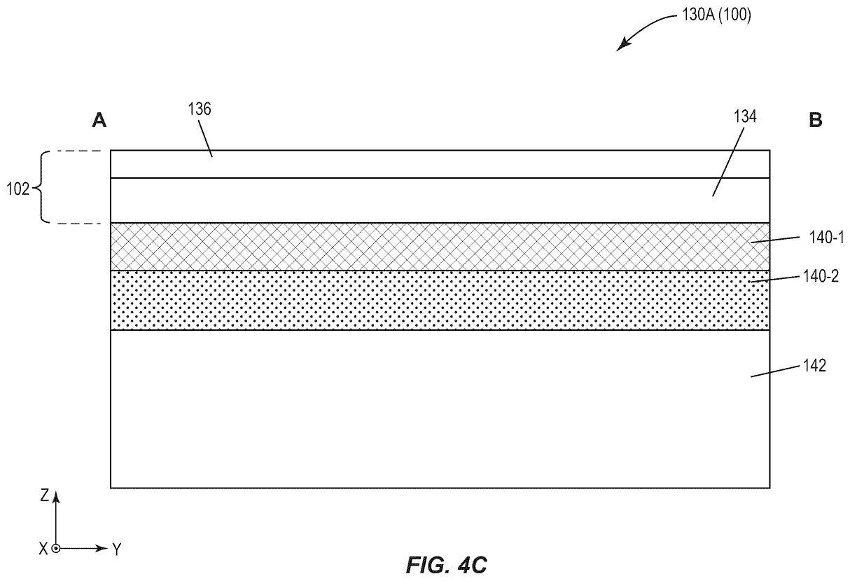

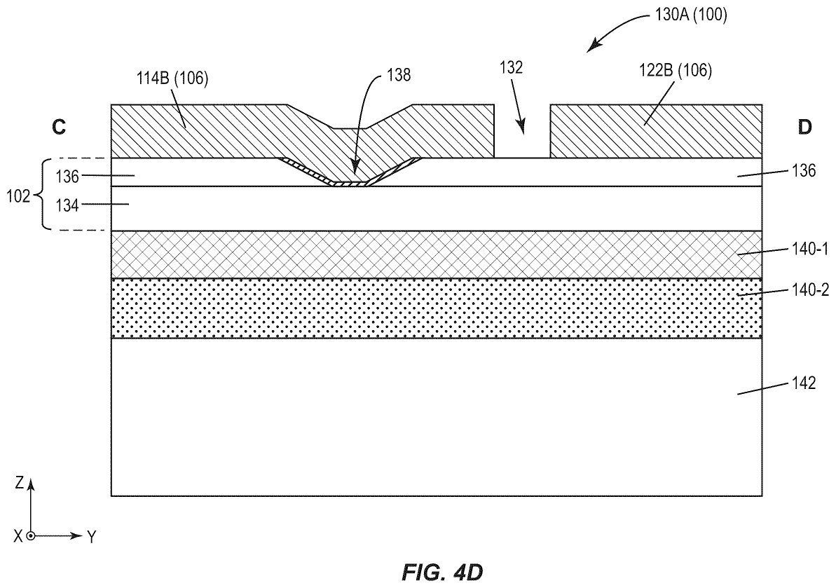

FIGS. 4A-4D illustrate an alternative implementation of the edge regions 128 according to some embodiments. FIG. 4A is a view of the first edge portion 130A, while FIGS. 4B-4D are different cross-sectional views of the first edge portion 130A. FIG. 4B is a cross-sectional view along the E-F dashed line in the resonator's propagation direction (i.e., in the x direction), FIG. 4C is a cross-sectional view along the A-B dashed line (in the y direction) through the electrode width gap 131, and FIG. 4D is a cross-sectional view along the C-D dashed line on the electrode finger 114 and its corresponding dummy electrode 122 (in the y direction). For clarity, only certain dummy electrodes and certain electrode fingers are labeled with reference numbers.

Herein, the first edge region 128A is still realized in the IDT 106 by a thickness variation within the piezoelectric structure 102 to achieve regions of different velocities in the transverse direction (i.e., the y direction). The piezoelectric structure 102 still includes the lower piezoelectric region 134 and the upper piezoelectric region 136 with a number of discrete piezoelectric trenches 138. The thickness of the piezoelectric structure 102 within the piezoelectric trenches 138 (i.e., only the thickness of the lower piezoelectric region 134) is thinner than a thickness of any remaining portions of the piezoelectric structure 102 (i.e., a combination thickness of the thickness of the lower piezoelectric region 134 and the thickness of the upper piezoelectric region 136). In this embodiment, each discrete piezoelectric trench 138 is located within the active area and underneath a corresponding electrode finger 114A/114B (details illustrated in FIGS. 4B and 4D). A portion of one electrode finger 114A/114B extends over a corresponding piezoelectric trench 138 in the y direction. For the purpose of this illustration (e.g., FIGS. 4B and 4D), each piezoelectric trench 138 may have a trapezoidal shape. In different applications, each piezoelectric trench 138 may have any proper shape in the x-y/x-z/y-z dimensions, such as a circular shape, an oval shape, a parabolic shape, a rounded shape, a square shape, a rectangular shape, a parallelogram shape, a trapezoidal shape or a polygonal shape. The first edge region 128A herein also achieves a different velocity compared to the other regions confined in the IDT 106.

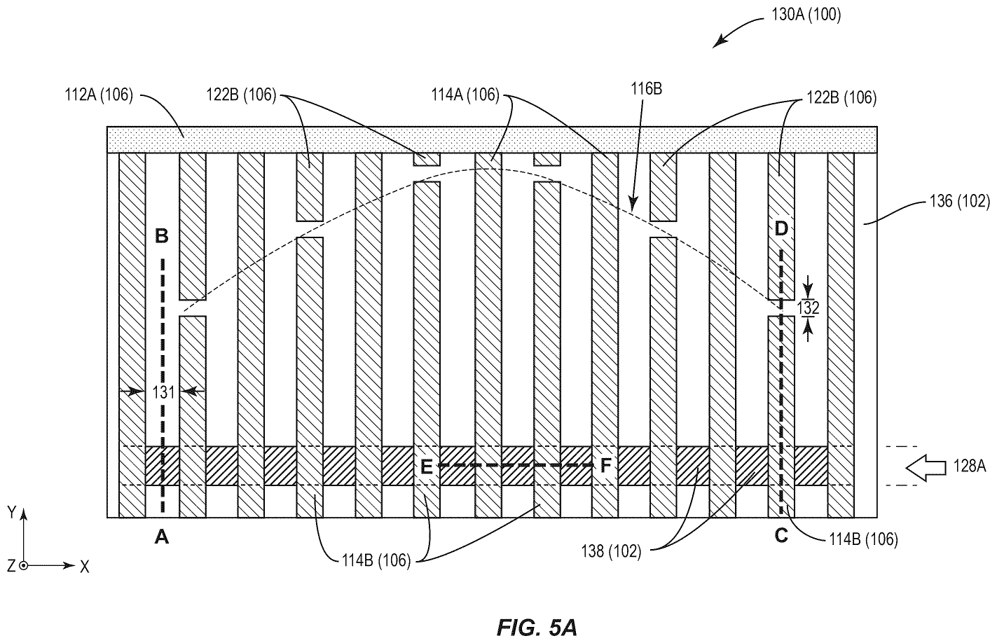

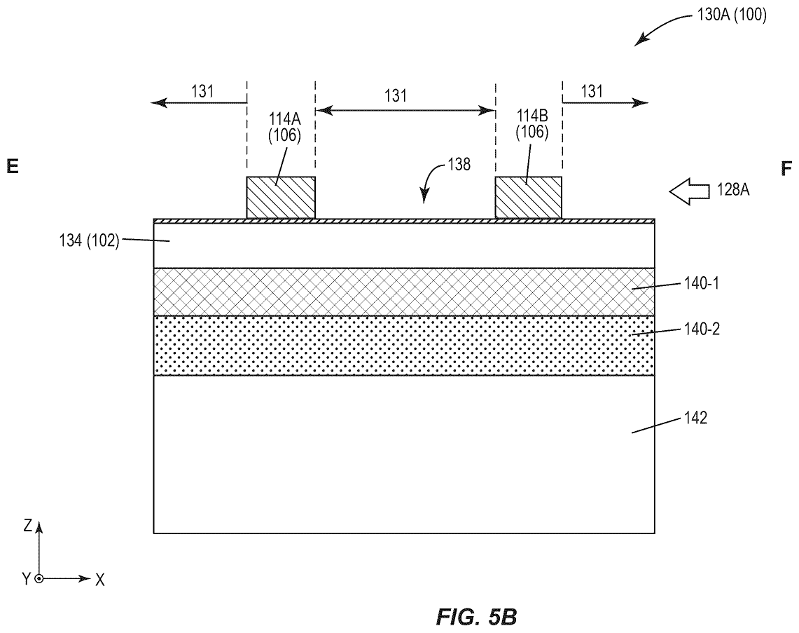

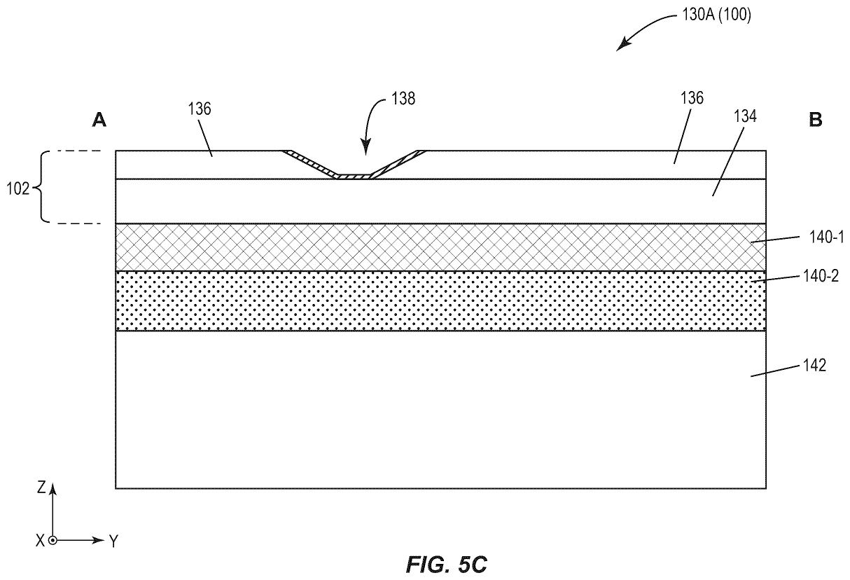

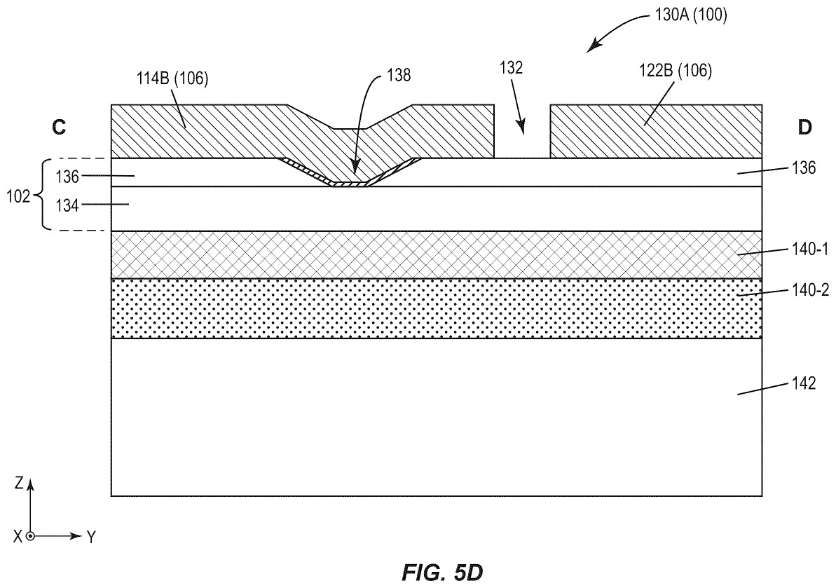

FIGS. 5A-5D illustrate another alternative implementation of the edge region 128 according to some embodiments. FIG. 5A is a top view of the first edge portion 130A, while FIGS. 5B-5D are different cross-sectional views of the first edge portion 130A. FIG. 5B is a cross-sectional view along the E-F dashed line in the resonator's propagation direction (i.e., in the x direction), FIG. 5C is a cross-sectional view along the A-B dashed line (in the y direction) through the electrode width gap 131, and FIG. 5D is a cross-sectional view along the C-D dashed line on the electrode finger 114 and its corresponding dummy electrode 122 (in the y direction). For clarity, only certain dummy electrodes and certain electrode fingers are labeled with reference numbers.

Herein, the first edge region 128A is still realized in the IDT 106 by a thickness variation within the piezoelectric structure 102 to achieve regions of different velocities in the transverse direction (i.e., the y direction). The piezoelectric structure 102 includes the lower piezoelectric region 134 and the upper piezoelectric region 136 with one continuous piezoelectric trench 138. The thickness of the piezoelectric structure 102 within the piezoelectric trench 138 (i.e., only the thickness of the lower piezoelectric region 134) is thinner than a thickness of any remaining portions of the piezoelectric structure 102 (i.e., a total thickness of the thickness of the lower piezoelectric region 134 and the thickness of the upper piezoelectric region 136). In this embodiment, the piezoelectric trench 138 is located within the active area and continuously extends in the x direction. The piezoelectric trench 138 extends at least across certain electrode fingers 114A/114B and the electrode width gaps 131 among these electrode fingers 114A/114B. A portion of each of these certain electrode fingers 114A/114B extends over the piezoelectric trench 138 in the y direction. The first edge region 128A herein may achieve a slower region than the other regions confined in the IDT 106.

FIGS. 3A-5D illustrate exemplary implementations of the edge region 128A/128B by introducing one or more piezoelectric trenches 138 in the piezoelectric structure 102 (i.e., enabling a thickness variation within the piezoelectric structure 102). Other configurations/implementations may also be applied to the edge region 128A/128B. In summary, the design of the one or more piezoelectric trenches 138 allows large degrees of freedom in position, size (e.g., depth, length, and/or width), and shape.

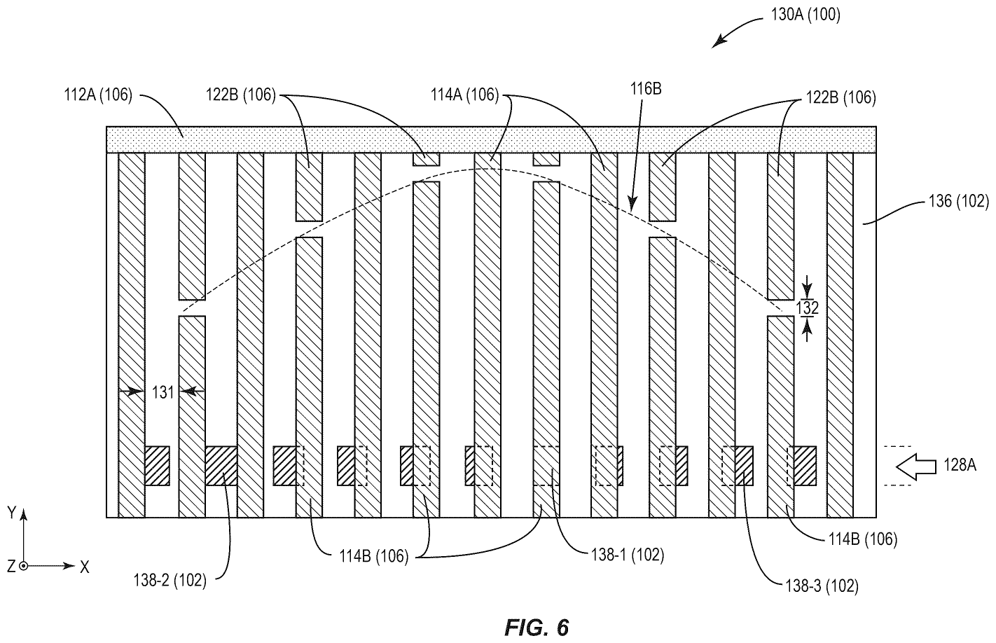

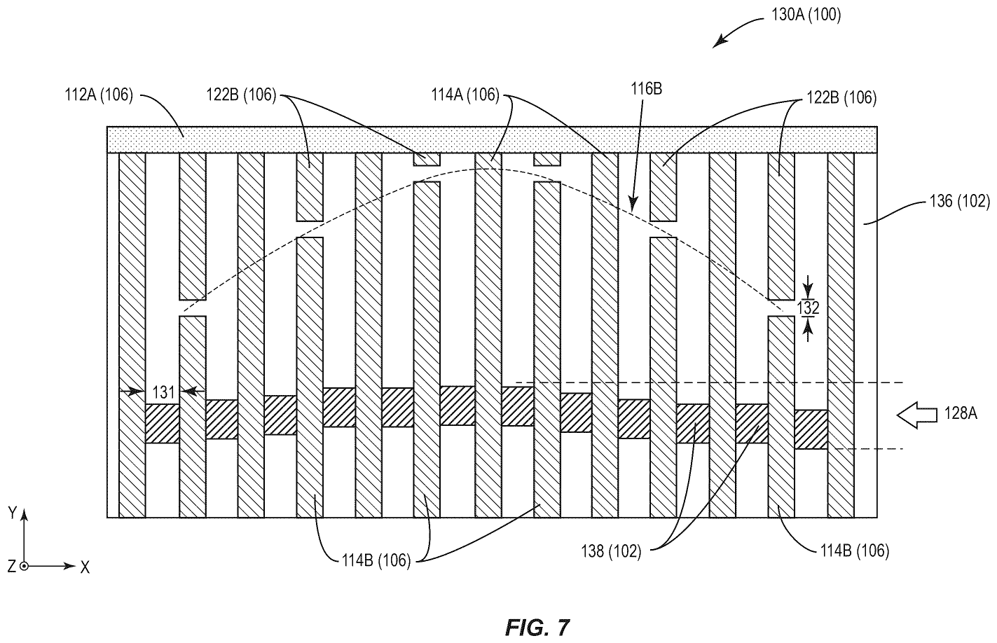

The one or more piezoelectric trenches 138 may be formed below and/or between certain electrode fingers 114A/114B. As illustrated in FIG. 6, some of the piezoelectric trenches 138 (e.g., piezoelectric trenches 138-1) may be below corresponding electrode fingers 114, some of the piezoelectric trenches 138 (e.g., piezoelectric trenches 138-2) may be laterally between corresponding electrode fingers 114, and some of the piezoelectric trenches 138 (e.g., piezoelectric trenches 138-3) may be partially below corresponding electrode fingers 114 and extend into the electrode width gaps 131 between the corresponding electrode fingers 114. Herein, the piezoelectric trenches 138 may be formed before the IDT 106 is formed, and do not need to follow the periodicity of the electrode finger 114 in the x direction (i.e., each piezoelectric trench 138 may or may not be aligned with a corresponding electrode finger 114 in the x direction, possible shift/offset in the x direction). In addition, the piezoelectric trenches 138 may have shifts in the y direction, as illustrated in FIG. 7. Herein, the piezoelectric trenches 138 are not arranged along the x direction but have different shifts/offsets in the y direction so as to form a parabolic shape, a curve shape, or any other suitable shape.

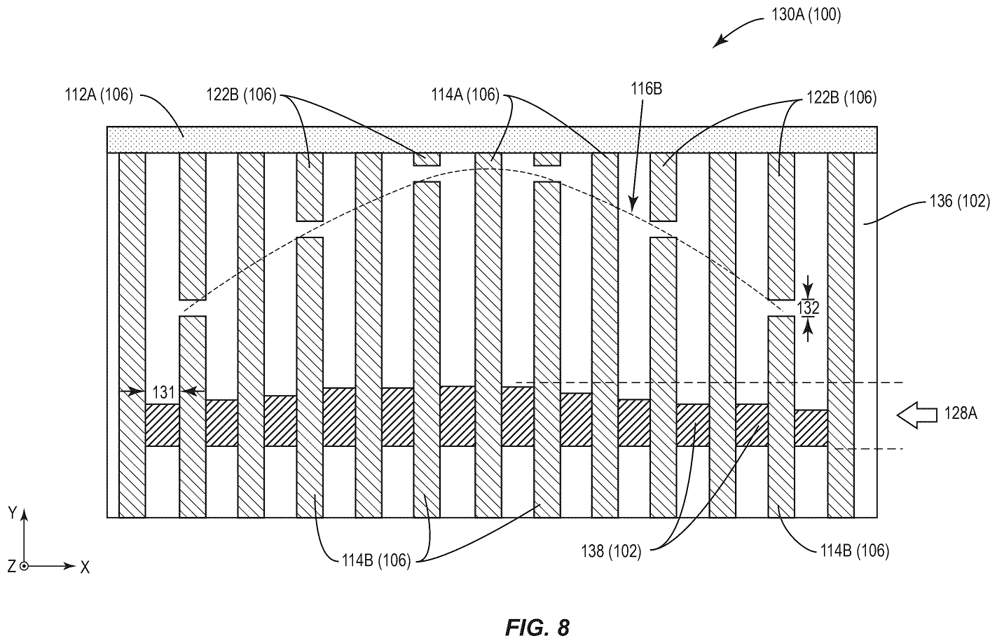

As shown in FIGS. 3A, 4A, and 5A, the piezoelectric trench(es) 138 may have a uniform depth, a uniform width, and a uniform length. In some embodiments, the one or more piezoelectric trenches 138 may have variations in depth (i.e., in the z direction), in width (i.e., in the x direction), and/or in length (i.e., in the y direction). For a non-limiting example, when the one or more piezoelectric trenches 138 include multiple discrete piezoelectric trenches 138, each piezoelectric trench 138 may have a different length (in the y direction), as illustrated in FIG. 8. The lengths of the piezoelectric trenches 138 may gradually increase/decrease in a repeated pattern (e.g., shorter lengths=>longer lengths=>shorter lengths=>longer lengths and etc.). When the one or more piezoelectric trenches 138 include one continuous piezoelectric trench 138, the continuous piezoelectric trench 138 may have a non-uniform but variable length in the y direction (not shown).

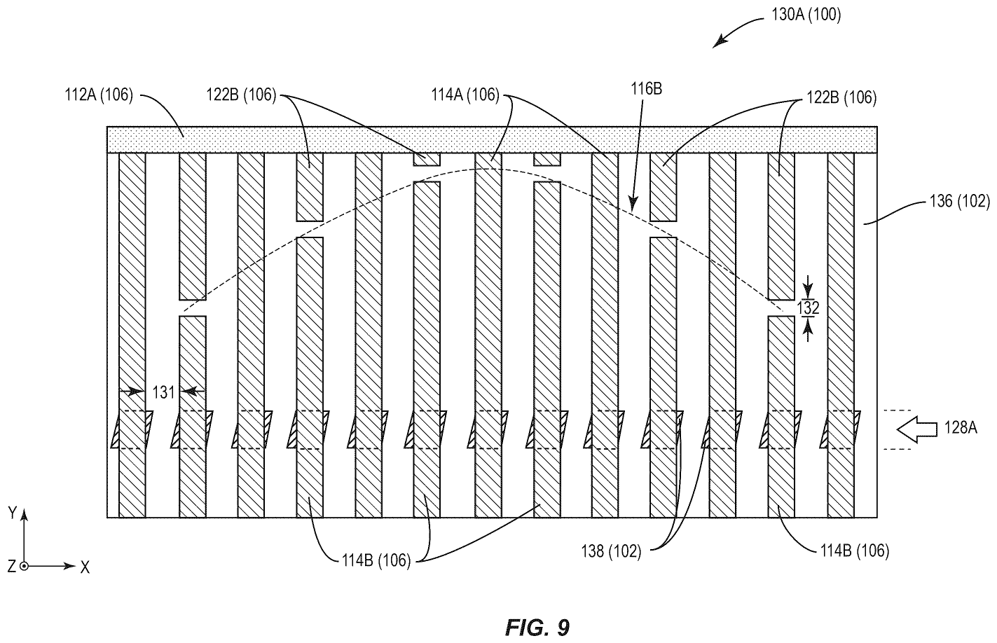

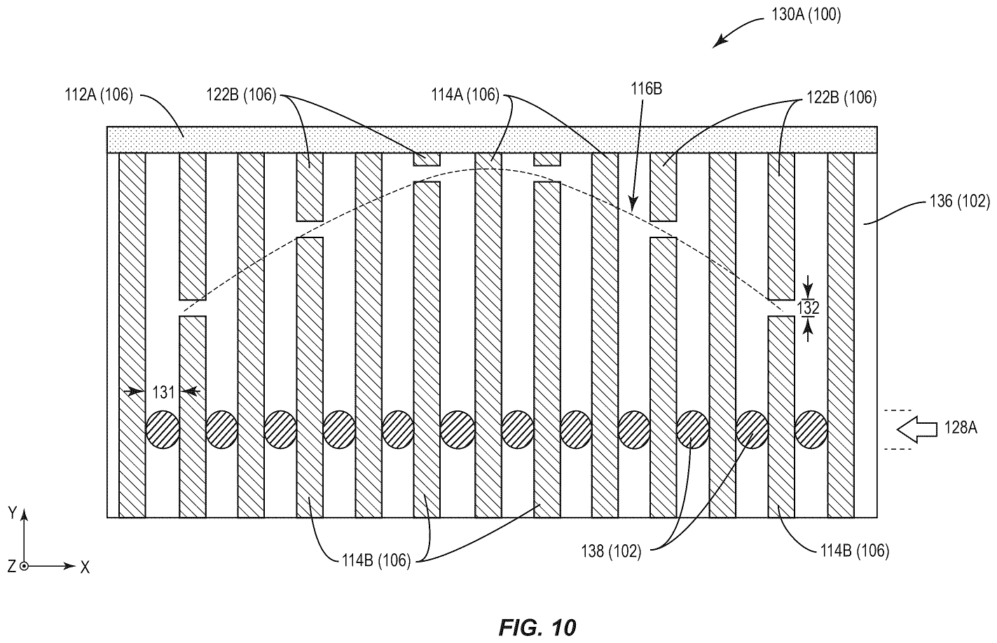

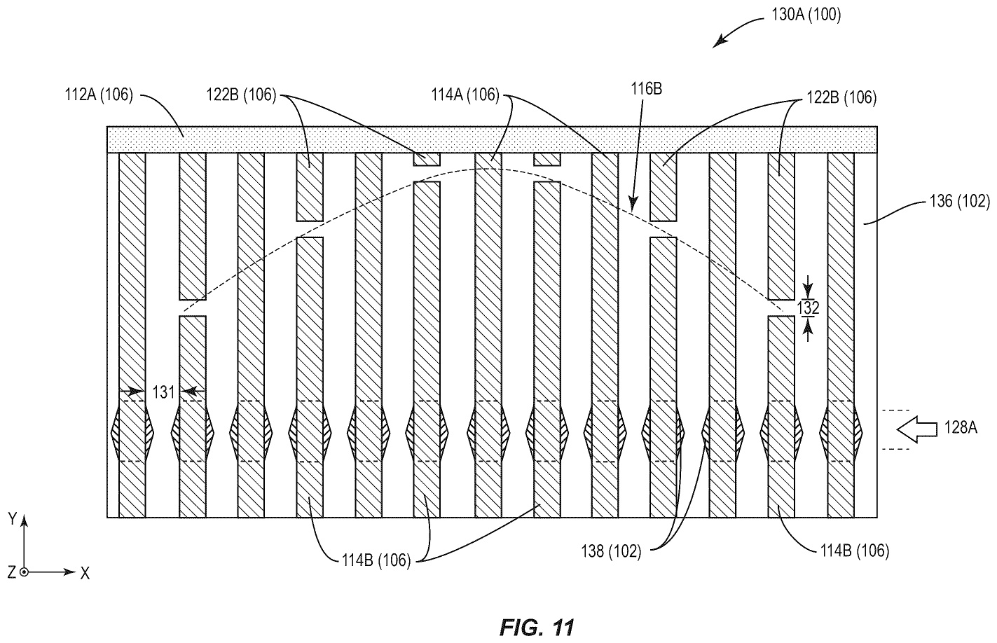

FIGS. 9-11 illustrate exemplary shapes of the piezoelectric trenches 138 in the x-y dimensions. In FIG. 9, each piezoelectric trench 138 has a parallelogram shape in the x-y dimensions and resides underneath a corresponding electrode finger 114A/114B. In FIG. 10, each piezoelectric trench 138 has an oval shape in the x-y dimensions and resides between adjacent electrode fingers 114A and 114B. In FIG. 11, each piezoelectric trench 138 has a hexagon shape in the x-y dimensions and partially resides underneath the corresponding electrode finger 114A/114B.

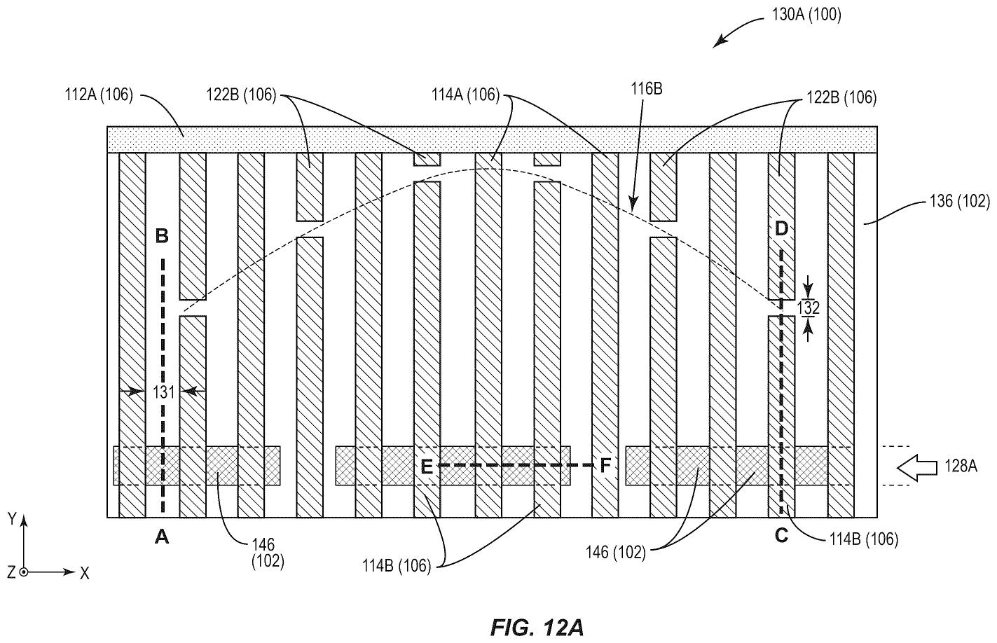

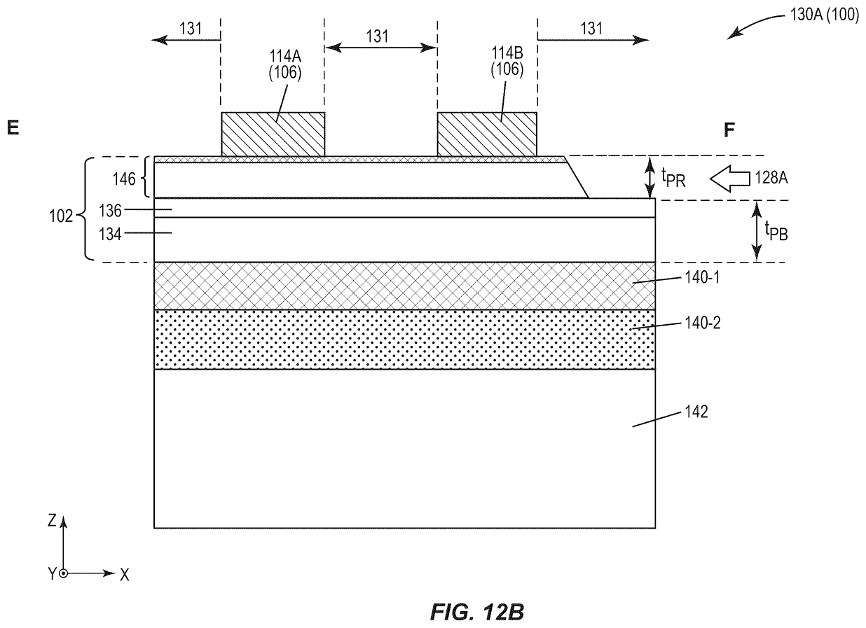

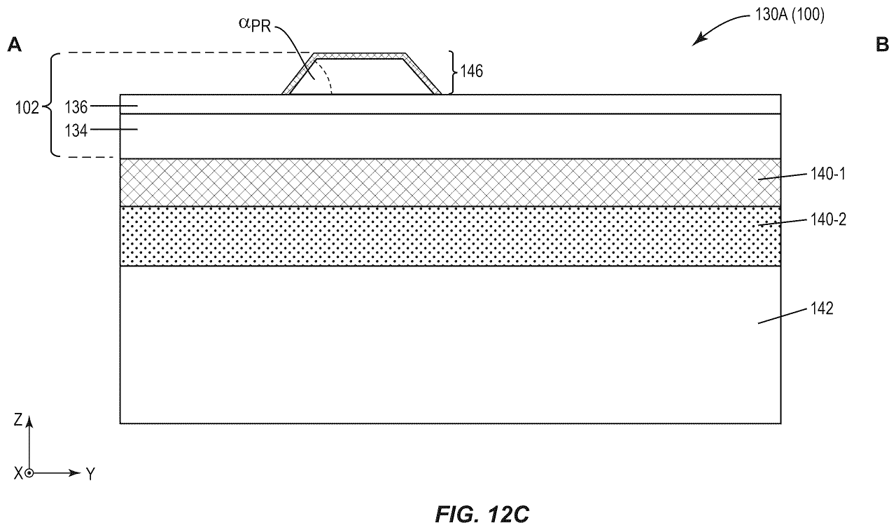

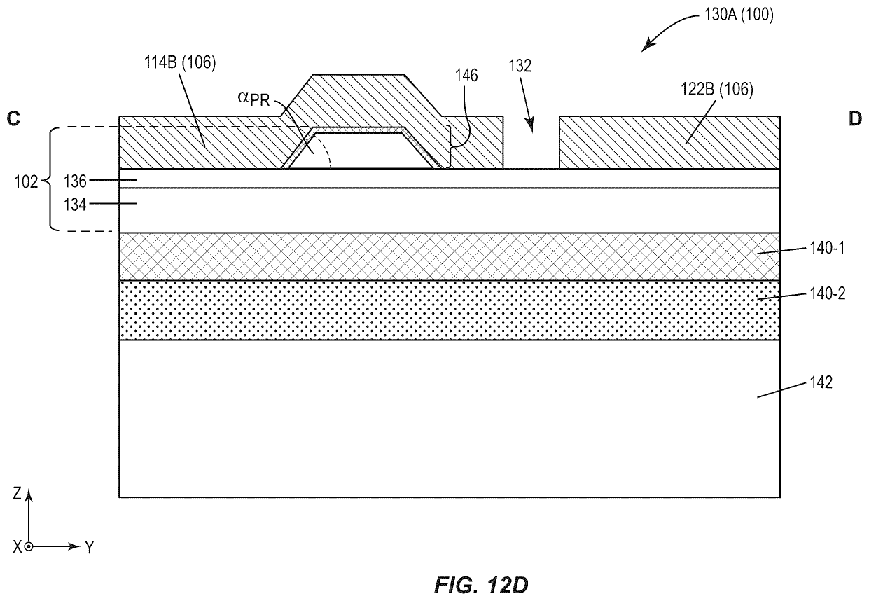

In some embodiments, instead of the piezoelectric trench(es) 138, the piezoelectric structure 102 may include an inverse configuration of at least one piezoelectric trench 138, which is called a piezoelectric ridge, to realize the edge region 128A/128B. As such, the edge region 128A/128B may have a different thickness compared to the other regions confined in the IDT 106, so as to achieve a different velocity compared to the other regions confined in the IDT 106. FIGS. 12A-12D illustrate an implementation of the edge region 128, which utilizes the thickness variation within the piezoelectric structure 102 including one or more piezoelectric ridges 146. Herein and hereafter, the pattern shading on top of the piezoelectric ridges 146 is used solely to clearly indicate locations of the piezoelectric ridges 146 and does not represent any additional material.

FIG. 12A is a view of the first edge portion 130A, while FIGS. 12B-12D are different cross-sectional views of the first edge portion 130A. FIG. 12B is a cross-sectional view along the E-F dashed line in the resonator's propagation direction (i.e., in the x direction), FIG. 12C is a cross-sectional view along the A-B dashed line (in the y direction) through the electrode width gap 131, and FIG. 12D is a cross-sectional view along the C-D dashed line on the electrode finger 114 and its corresponding dummy electrode 122 (in the y direction). For clarity, only certain dummy electrodes and certain electrode fingers are labeled with reference numbers.

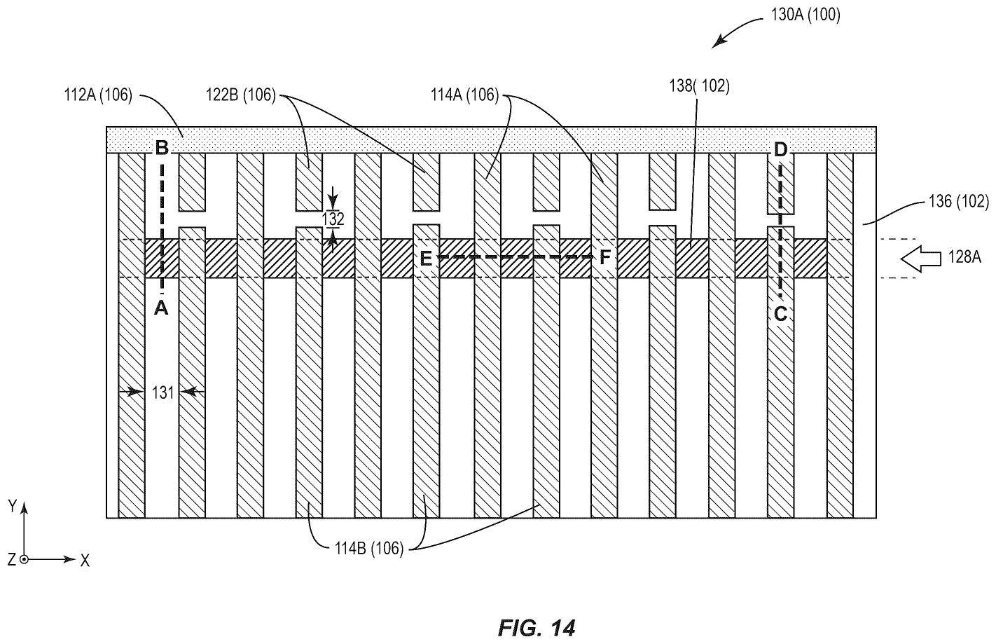

For the purpose of this illustration, the piezoelectric structure 102 includes a number of discrete piezoelectric ridges 146, each of which is located within the active area and extends in the x direction. Each piezoelectric ridge 146 extends underneath a couple of electrode fingers 114A/114B and the electrode width gaps 131 in between. In different applications, the piezoelectric structure 102 may include fewer or more piezoelectric ridges 146, each of which extends underneath fewer or more electrode fingers 114A/114B. In a non-limiting example, the piezoelectric structure 102 may only include one continuous piezoelectric ridge 146 that continuously extends in the x direction and underneath certain electrode fingers 114A/114B and the electrode width gaps 131 among these electrode fingers 114A/114B (see FIG. 14). In another non-limiting example, the piezoelectric structure 102 may include discrete piezoelectric ridges 146 that only extend underneath one electrode finger 114A/114B or between two adjacent electrode fingers 114A and 114B (not shown).

Herein, the piezoelectric structure 102 still includes the lower piezoelectric region 134 and the upper piezoelectric region 136, and further includes the one or more piezoelectric ridges 146, which are formed over the upper piezoelectric region 136 and confined within the first edge region 128A (details illustrated in FIG. 12B). Each piezoelectric ridge 146 has a thickness t_{PR}. In this illustration, each of the lower piezoelectric region 134 and the upper piezoelectric region 136 has a uniform thickness (i.e., the upper piezoelectric region 136 without the piezoelectric trenches 138), where a combination thickness of the lower piezoelectric region 134 and the upper piezoelectric region 136 is the base thickness of the piezoelectric structure 102, t_{PB}. It is clear that a thickness of the piezoelectric structure 102 with the piezoelectric ridges 146 (i.e., a combination thickness of the base thickness t_{PB} and the thickness of one piezoelectric region piezoelectric ridge 146 t_{PR}) is thicker than the base thickness of any remaining portions of the piezoelectric structure 102 t_{PB}. The first edge region 128A herein may achieve a faster region than other regions confined in the IDT 106.

By utilizing the piezoelectric ridges 146 in the piezoelectric structure 102, a velocity enhancement can be achieved in the edge region(s) 128. A ratio between the thickness of the piezoelectric ridge 146 t_{PR} and the base thickness of the piezoelectric structure 102 t_{PB} may be between 5% and 50%. The utilization of the piezoelectric ridges 146 can provide enough velocity contrast within the IDT 106.

For the purpose of this illustration (FIGS. 12C and 12D), each piezoelectric ridge 146 has a one-step configuration and has a rectangular shape in x-y dimensions and a trapezoidal shape in y-z dimensions. A ridge sidewall angle α_{PR}, which is an angle between the bottom surface of one piezoelectric ridge 146 and a sidewall of one piezoelectric ridge 146, is smaller than 90°. In different applications, each piezoelectric ridge 146 may have any proper shape in the x-y/x-z/y-z dimensions, such as a circular shape, an oval shape, a parabolic shape, a rounded shape, a square shape, a rectangular shape, a parallelogram shape, a trapezoidal shape, or a polygonal shape. In addition, one piezoelectric ridge 146 may have a two-step or multiple-step configuration (e.g., a multi-layer cake configuration). Furthermore, for multiple piezoelectric ridges 146, the piezoelectric ridges 146 may have different shapes and/or different thicknesses. For the continuous piezoelectric ridge 146, the piezoelectric ridges 146 may have variations in shape and/or in thickness.

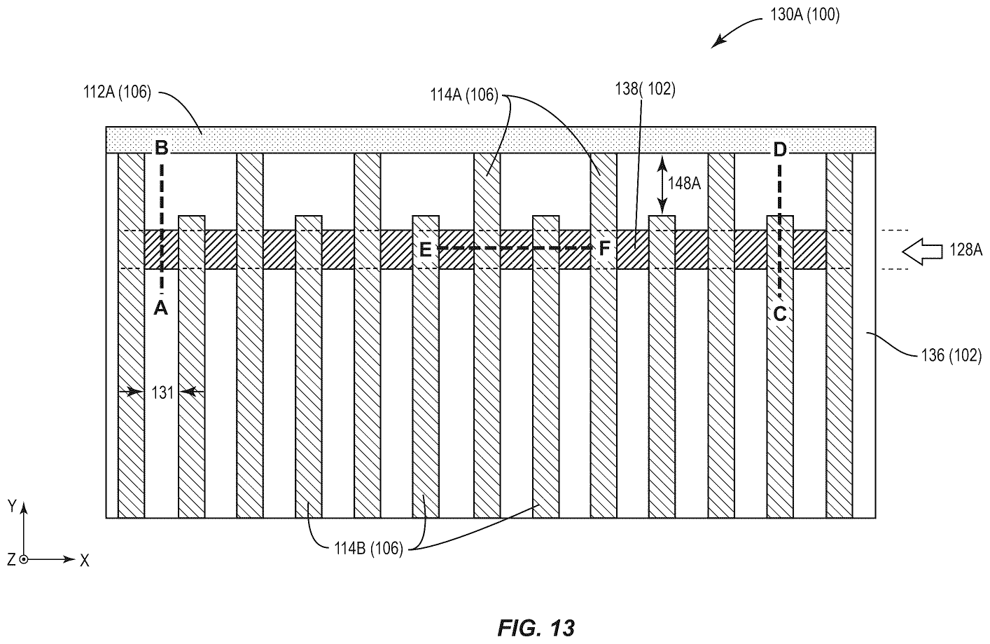

As illustrated in FIGS. 2-12A, the IDT 106 can be apodized with the apodization edges 116A and 116B, which confine the lengths of the electrode fingers 114A/114B and the corresponding dummy electrodes 122A/122B. In some embodiments, the IDT 106 may not be apodized and may not include any dummy electrode, as illustrated in FIG. 13. Herein, each first electrode finger 114A still extends in the y-direction from the first busbar 112A, while each second electrode finger 114B still extends in the y-direction from the second busbar 112B (not shown). In addition, the second electrode fingers 114B extend towards the first busbar 112A with a first electrode length gap 148A in between (in the y direction). Each first electrode finger 114A extends towards the first busbar 112A with a second electrode length gap in between (in the y direction, not shown).

For the purpose of this illustration, the piezoelectric structure 102 includes at least one piezoelectric trench 138 that is located at ends of the second electrode fingers 114B adjacent to the first electrode length gap 148A (within the active area). There might be another piezoelectric trench 138 located at ends of the first electrode fingers 114A adjacent to the second electrode length gap (not shown). Herein, the piezoelectric trench 138 continuously extends in the x direction and across alternate first electrode fingers 114A, the second electrode fingers 114B, and the electrode width gaps 131 among these electrode fingers 114A/114B. In different applications, the at least one piezoelectric trench 138 may have various variations as described in previous embodiments. The first edge region 128A herein may achieve a slower region than the other regions confined in the IDT 106. Cross-sectional views along the E-F dashed line and the A-B dashed line are similar to illustrations shown in FIGS. 5B and 5C, respectively. A cross-sectional view along the C-D dashed line is similar to the illustration shown in FIG. 5D, but without the second dummy electrode 122B.

In some embodiments, the IDT 106 may include dummy electrodes 122A/122B, but may not be apodized (i.e., no apodization edges 116), as illustrated in FIG. 14. Herein, each second dummy electrode 122B still extends from the first busbar 112A in the y-direction towards a corresponding second electrode finger 114B, and each second dummy electrode 122B is positioned between two adjacent first electrode fingers 114A in the x direction. Similarly, each first dummy electrode 122A extends from the second busbar 112B in the y-direction towards a corresponding first electrode finger 114A, and each first dummy electrode 122A is positioned between two adjacent second electrode fingers 114B in the x direction (not shown). The transverse gap 132 between one dummy electrode 122 and the corresponding electrode finger 114 may have a dimension that is greater than zero. Different from the IDT 106 with apodization edges, in this embodiment, the second dummy electrodes 122B have a same length in the y direction (the first dummy electrodes 122A have a same length in the y direction, not shown), such that the transverse gaps 132 are aligned with each other in the x direction.

For the purpose of this illustration, the piezoelectric trench 138 is located at the ends of the second electrode fingers 114B adjacent to the transverse gaps 132 (within the active area) and may continuously extend in the x direction and across alternate first electrode fingers 114A, the second electrode fingers 114B, and the electrode width gaps 131 among these electrode fingers 114A/114B. In different applications, the piezoelectric trench 138 may be located at the ends of the second dummy electrodes 122B adjacent to the transverse gaps 132, and continuously extend in the x direction and across alternate first electrode fingers 114A, the second dummy electrodes 122B, and the electrode width gaps 131 in between (not shown). In addition, there might be more than one piezoelectric trench 138, each of which may have various variations as described in previous embodiments. The first edge region 128A herein may achieve a slower region than the other regions confined in the IDT 106. Cross-sectional views along the E-F dashed line, the A-B dashed line, and the C-D dashed line are similar to illustrations shown in FIGS. 5B, 5C, and 5D, respectively.

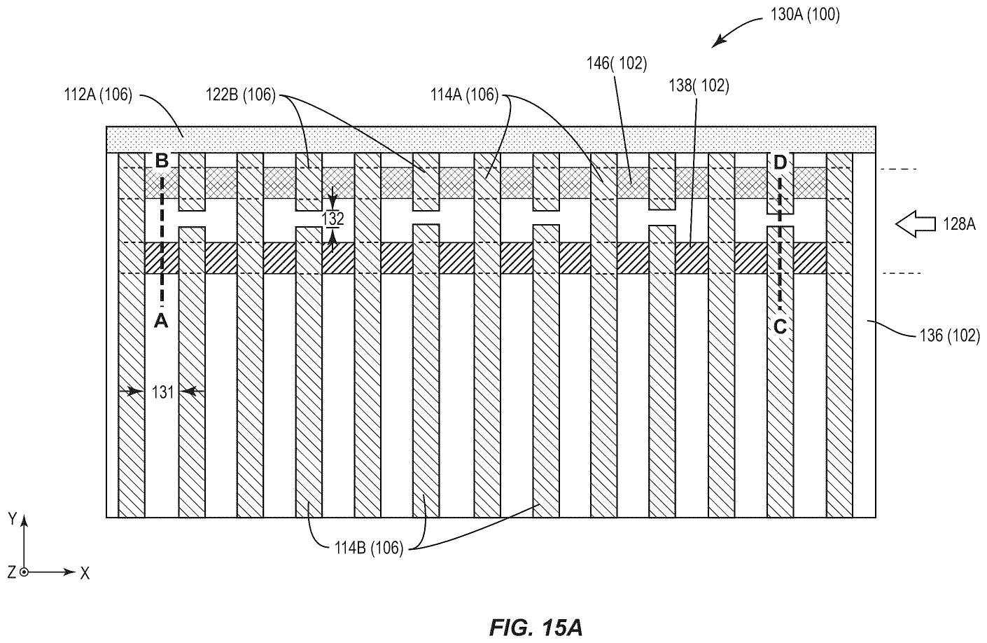

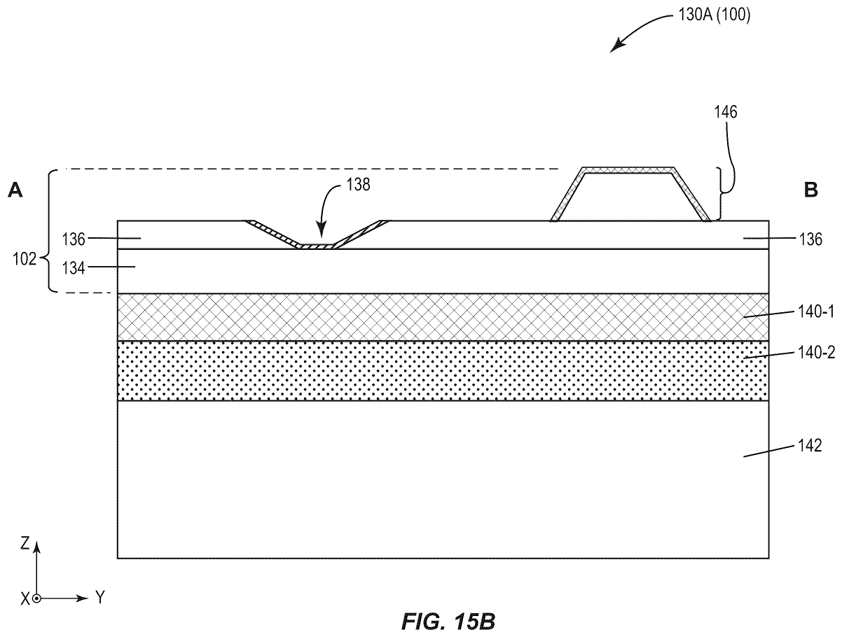

In some embodiments, the piezoelectric structure 102 may include both the piezoelectric trench(es) 138 and the piezoelectric ridge(s) 146, as illustrated in FIGS. 15A-15C. As such, the piezoelectric structure 102 may have regions that are locally thinner (e.g., the piezoelectric trench 138) and regions that are locally thicker (e.g., the piezoelectric ridge 146) for optimizing the geometry, and thereby further modifying the thickness variation of the piezoelectric structure 102 for best performance (e.g., to achieve large velocity contrasts). Transversely across the IDT 106, which regions are faster, and which are slower depends on the explicit choice of materials and thicknesses of the piezoelectric structure 102.

Herein, FIG. 15A is a view of the first edge portion 130A, FIG. 15B is a cross-sectional view along the A-B dashed line (in the y direction) through the electrode width gap 131, and FIG. 15C is a cross-sectional view along the C-D dashed line on the electrode finger 114 and its corresponding dummy electrode 122 (in the y direction). For clarity, only certain dummy electrodes and certain electrode fingers are labeled with reference numbers. For the purpose of this illustration, the continuous piezoelectric trench 138 is located at the ends of the second electrode fingers 114B adjacent to the transverse gaps 132 (within the active area), and continuously extends in the x direction and across alternate first electrode fingers 114A, the second electrode fingers 114B, and the electrode width gaps 131 among these electrode fingers 114A/114B. The continuous piezoelectric ridge 146 is located at the ends of the second dummy electrodes 122B adjacent to the transverse gaps 132 (within the inactive area), and continuously extends in the x direction and underneath alternate first electrode fingers 114A, the second dummy electrodes 122B, and the electrode width gaps 131 in between. As such, the first edge region 128A may achieve both velocity reduction (due to the piezoelectric trench 138) and velocity enhancement (due to the piezoelectric ridge 146) compared to other regions confined in the IDT 106. The first edge region 128A has advantages in suppression of transverse mode and suppression of transverse leakage. In different applications, there might be more than one piezoelectric trench 138 and/or more than one piezoelectric ridge 146. Each piezoelectric trench 138 and each piezoelectric ridge 146 may have various variations as described in previous embodiments.

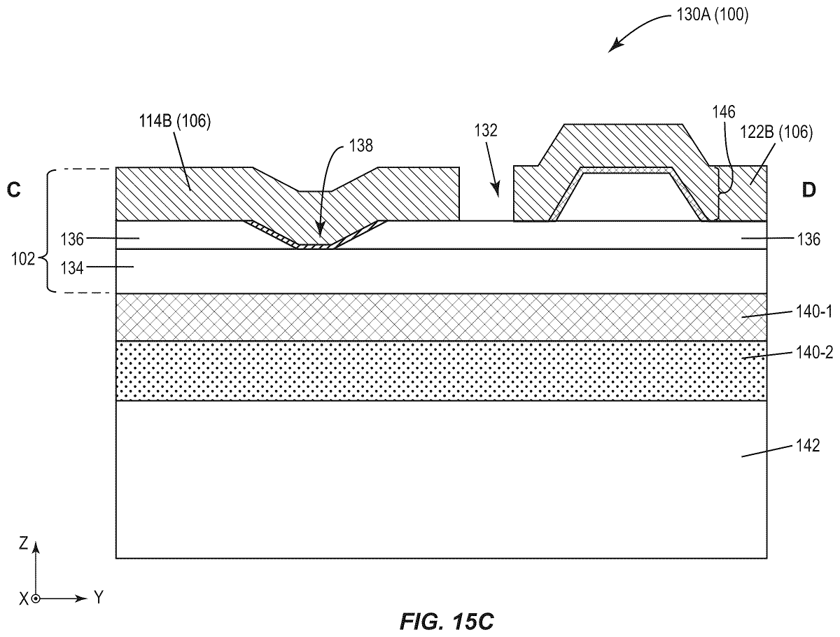

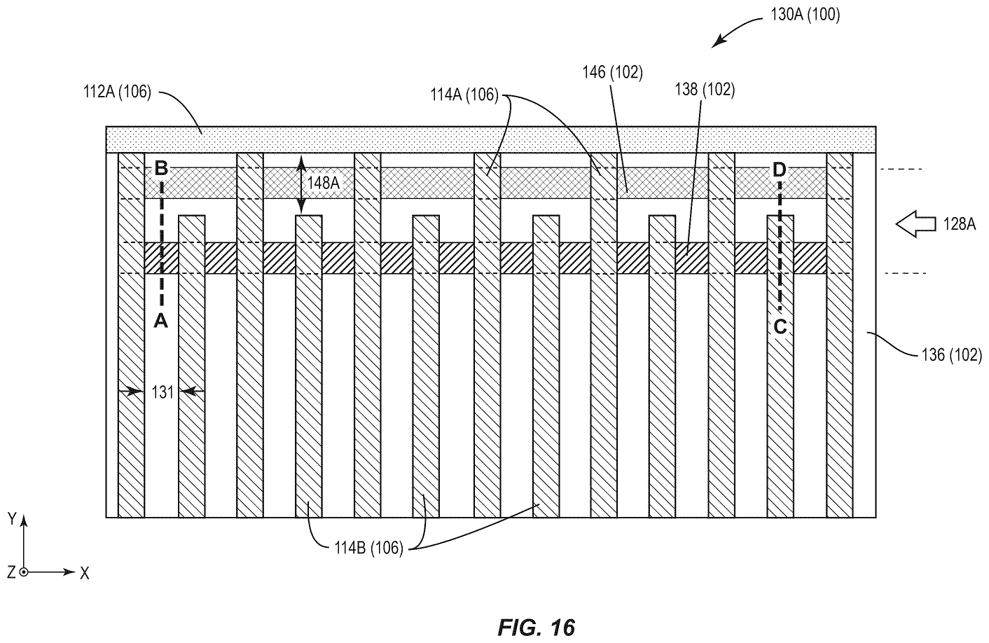

FIG. 16 illustrates an exemplary case that the IDT 106 does not have dummy electrodes 122 while the piezoelectric structure 102 includes both the piezoelectric trench 138 and the piezoelectric ridge 146. Herein, the continuous piezoelectric trench 138 is located at the ends of the second electrode fingers 114B adjacent to the first electrode length gap 148A, and still continuously extends in the x direction and across alternate first electrode fingers 114A, the second electrode fingers 114B, and the electrode width gaps 131 among these electrode fingers 114A/114B. The continuous piezoelectric ridge 146 continuously extends in the x direction, underneath the first electrode fingers 114A, and across gaps between adjacent first electrode fingers 114A. As such, the first edge region 128A may achieve both velocity reduction (due to the piezoelectric trench 138) and velocity enhancement (due to the piezoelectric ridge 146) compared to other regions confined in the IDT 106. A cross-sectional view along the A-B dashed line is similar to illustrations shown in FIG. 15B. A cross-sectional view along the C-D dashed line is similar to the illustration shown in FIG. 15C, but without the second dummy electrode 122B.

Within the piezoelectric structure 102, the thickness profile may change with discrete steps (e.g., the piezoelectric trench 138 and/or the piezoelectric ridge 146 has a rectangular shape in the x-z dimensions) or may change in a gradual transition (e.g., the piezoelectric trench 138 and/or the piezoelectric ridge 146 has a trapezoidal shape/a parabolic shape in the x-z dimensions). The gradual transition in the thickness profile of the piezoelectric structure 102 enables smoother transitions in the velocity profile, which enables a better matching of the mode shape to the excitation and can suppress unwanted effects including a scattering loss due to rapid velocity change. For a non-limiting example, by tuning the sidewall angle α_{PT}/α_{PR} of the piezoelectric trench 138/the piezoelectric ridge 146 (e.g. does not have to be a trapezoidal shape) or by tuning a shape of the piezoelectric trench 138 and/or the shape of the piezoelectric ridge 146, the changes of the velocity profile can be modulated transversely across the IDT 106. Continuous velocity profile changes with linear or non-linear transitions become possible.

In some applications, the thickness profile changes in the piezoelectric structure 102 as described above may be combined with the piston mode described in U.S. Pat. No. 7,939,989 B2. As such, continuous thickness changes (in the piezoelectric structure 102 along the resonator's propagation direction) and continuous width changes (in certain areas of the electrode fingers 114A/114B along the resonator's propagation direction) can be used together for continuous changes of velocity across the IDT 106.

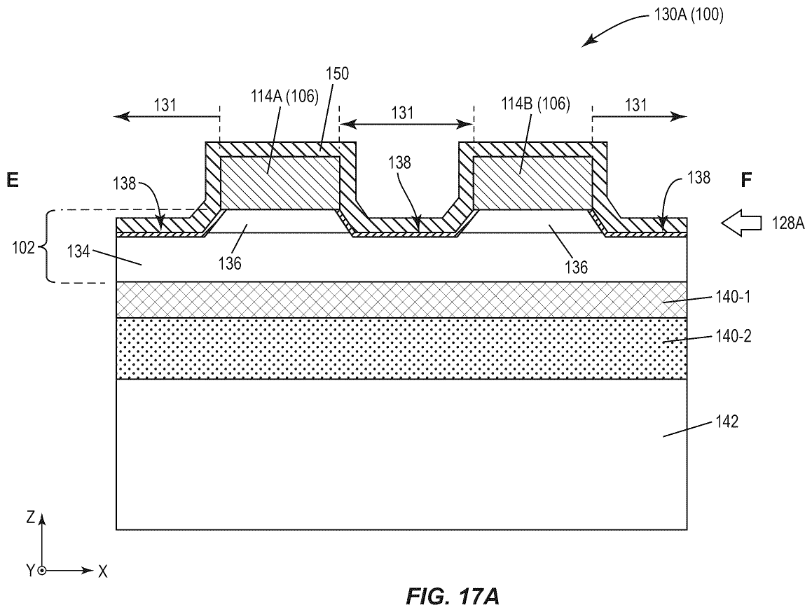

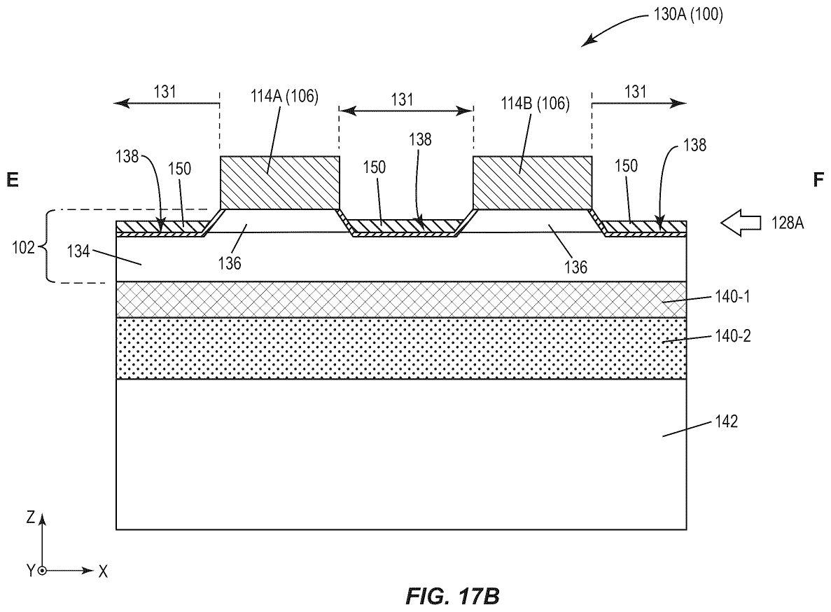

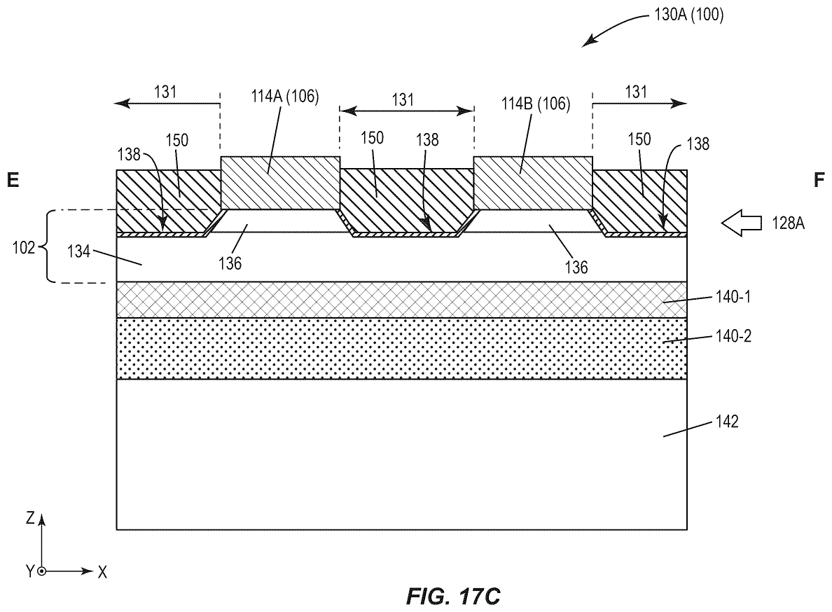

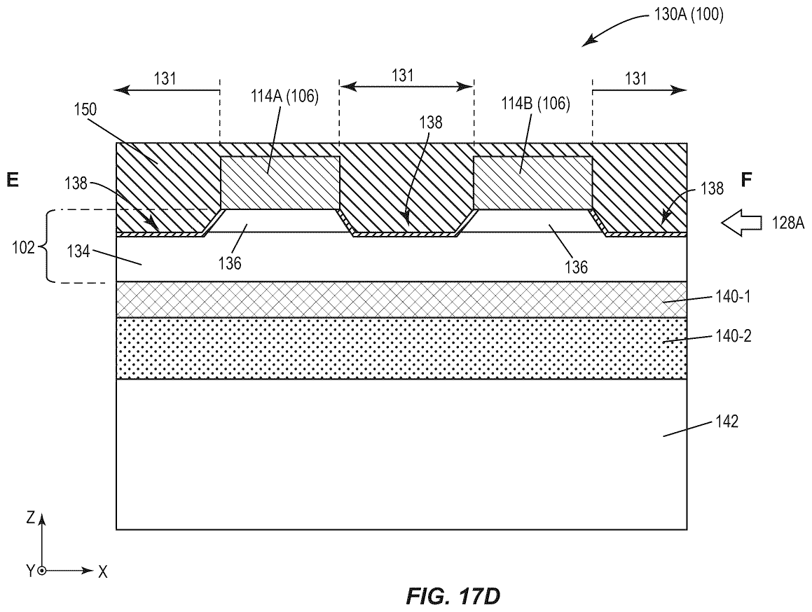

Typically, the SAW resonator 100 may further include a passivation structure for temperature compensation, avoiding moisture intrusion, and/or protecting from failure mechanisms under large power (e.g., migration of materials, including acoustomigration). The passivation structure is omitted in FIGS. 1-16 for simplicity and clarity. Different materials and different topographies can be employed in the passivation structure for different benefits. FIGS. 17A-17D illustrate several representative configurations of a passivation structure 150. The geometry of the IDT 106 and the piezoelectric structure 102 is the same as shown in FIG. 3B, but the concept of the passivation structure 50 is not limited to this geometry.

The passivation structure 150 may include one or more dielectric layers (not shown), which may be formed of silicon dioxide, silicon nitride, silicon oxynitride, and/or titanium oxide among others. In some embodiments, the passivation structure 150 may be a conformal coating, as shown in FIG. 17A. For a non-limiting example, the passivation structure 150 may have a uniform thickness and does not change the geometries generated by the piezoelectric structure 102 and the IDT 106. In some embodiments, the passivation structure 150 may partially fill each piezoelectric trench 138, as shown in FIG. 17B. For a non-limiting example, the passivation structure 150 may have a uniform thickness, which is less than the depth of the piezoelectric trench 138. As such, top portions of the upper piezoelectric region 136 are exposed through the passivation structure 150, and no portion of the electrode fingers 114A/114B are covered by the passivation structure 150. In some embodiments, the passivation structure 150 may fully cover exposed surfaces of the piezoelectric structure 102 and partially fill gaps within the IDT 106 (i.e., fills gaps among the electrode fingers 114A/114B), as illustrated in FIG. 17C. Herein, each piezoelectric trench 138 is fully filled with the passivation structure 150, and each electrode width gap 131 between adjacent electrode fingers 114A/114B is partially filled with the passivation structure 150 (i.e., side surfaces of each electrode finger 114A/114B are partially encapsulated by the passivation structure 150). In some embodiments, the passivation structure 150 may fully cover exposed surfaces of the piezoelectric structure 102 and the IDT 106, as illustrated in FIG. 17D. Herein, the passivation structure 150 fills each piezoelectric trench 138 and each electrode width gap 131 between adjacent electrode fingers 114A/114B and provides a planarized top surface.

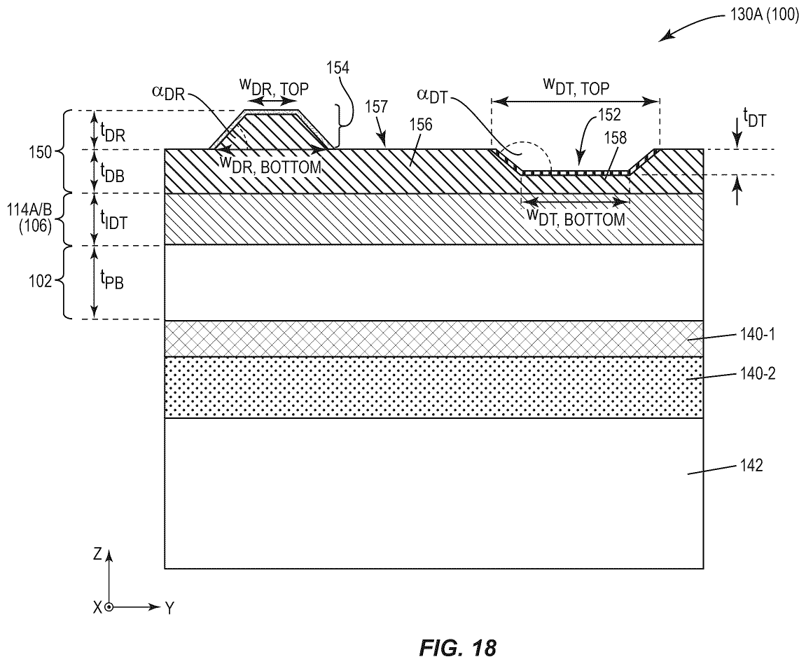

It is noticed that since the passivation structure 150 has flexibility in thickness and geometry, the passivation structure 150 may also be utilized to change resonance velocity in the transverse direction. The passivation structure 150, similar to the piezoelectric structure 102, can be locally changed in thickness (thicker or thinner) to optimize the transverse geometry of the SAW resonator 100. FIG. 18 illustrates a cross-sectional view of the first edge portion 130A of the SAW resonator 100 through one electrode finger (in the y direction). For the purpose of this illustration, the piezoelectric structure 102 has a uniform base thickness t_{PB}, while the passivation structure 150 has a varying thickness profile, specifically including a passivation trench 152 (e.g., thicker thickness) and a passivation ridge 154 (e.g., thinner thickness). Herein and hereafter, the pattern shading over the passivation trench 152 is used solely to clearly indicate locations of the passivation trench 152 and does not represent any additional material. Similarly, the pattern shading on top of the passivation ridge 154 is used solely to clearly indicate locations of the passivation ridge 154 and does not represent any additional material.

The passivation structure 150 may cover the IDT 106 and exposed surfaces of the piezoelectric structure 102 (not shown). In different applications, the passivation structure 150 may have no passivation trenches 152 or more passivation trenches 152 and/or no passivation ridges 154 or more passivation ridges 154. In addition, the passivation structure 150 may only partially cover the IDT 106 and the exposed surfaces of the piezoelectric structure 102 (not shown). The thickness variation of the passivation structure 150 can be used solely for achieving velocity contrast in the transverse direction (i.e., slow/fast region), or can be combined with the thickness variation of the piezoelectric structure 102 (as described in previous embodiments) to achieve the velocity contrast in the transverse direction. If the thickness variation of the passivation structure 150 is not used for achieving the velocity contrast in the transverse direction, the passivation structure 150 may be omitted.

In detail, the passivation structure 150 includes a passivation base 156, the passivation trench 152, and the passivation ridge 154. The passivation base 156 has a thickness t_{DB} and provides a planarized top surface 157, the passivation trench 152 has a depth tor extending from the top surface 157 of the passivation base 156 towards a bottom surface of the passivation base 156, and the passivation ridge 154 has a thickness tor protruding from the top surface 157 of the passivation base 156. A relative dielectric trench depth t_{DT,rel} (t_{DT,rel}=(t_{DT}/t_{DB})*100%) is defined as a ratio between the depth of the passivation trench 152 and the thickness of the passivation base 156 in the z direction. The relative dielectric trench depth t_{DT,rel} can have any value between 0% and 100%. If the relative dielectric trench depth t_{DT,rel} is less than 100%, there is a passivation residue 158 underneath a corresponding passivation trench 152. Herein, a thickness of the passivation structure 150 within the passivation trench 152 (i.e., t_{DB}-t_{DT}) is thinner than the thickness of the passivation base 156, and a thickness of the passivation structure 150 within the passivation ridge 154 (i.e., t_{PB}+t_{DR}) is thicker than the thickness of the passivation base 156. The first edge region 128A of the SAW resonator 100 herein may achieve both a slower region (e.g., within the passivation trench 152) and a faster region (e.g., within the passivation ridge 154) in the transverse direction than other regions confined in the IDT 106 (e.g., covered by the passivation base 156 without the passivation trench 152 and the passivation ridge 154). The velocity change may also have the opposite direction (slower instead of faster and faster instead of slower), depending on the employed dielectric material and the underlaying stack (piezoelectric material and thickness and handle material).

For the purpose of this illustration, the passivation trench 152 has a one-step configuration and has a trapezoidal shape in the y-z dimensions, which has a top trench width W_{DT,top} and a bottom trench width W_{DT,bottom} smaller than the top trench width W_{DT,top}. A trench sidewall angle α_{DT}, which is an angle between the bottom surface of the passivation trench 152 and a sidewall of the passivation trench 152, is typically larger than 90°, but not limited to (e.g., the trench sidewall angle α_{DT} may be equal to or smaller than) 90°. Similarly, the passivation ridge 154 has a one-step configuration and has a trapezoidal shape in the y-z dimensions, which has a top trench width W_{DR,top} and a bottom trench width W_{DR,bottom} greater than the top trench width W_{DR,top}. A ridge sidewall angle α_{DR}, which is an angle between the bottom surface of the passivation ridge 154 and a sidewall of the passivation ridge 154, is 90° or smaller. In different applications, the passivation trench 152 and/or the passivation ridge 154 may have any proper shape in the x-y/x-z/y-z dimensions, such as a circular shape, an oval shape, a parabolic shape, a rounded shape, a square shape, a rectangular shape, a parallelogram shape, a trapezoidal shape or a polygonal shape. In addition, the passivation trench 152 and/or the passivation ridge 154 may have a two-step or multiple-step configuration (e.g., an inverse multi-layer cake configuration/a multi-layer cake configuration). Furthermore, when the passivation structure 150 includes multiple discrete passivation trenches 152 and/or multiple discrete passivation ridges 154, the passivation trenches 152 may have different shapes and/or different depths and the passivation ridges 154 may have different shapes and/or different thicknesses. For one continuous passivation trench 152, the passivation trench 152 may have variations in shape and/or depth. For one continuous passivation ridge 154, the passivation ridge 154 may have variations in shape and/or thickness.

The passivation structure 150 has a similar design freedom as previously outlined for the piezoelectric structure 102 in size (e.g., depth, length, and/or width), shape, and location in relation to the IDT 106. Since the passivation structure 150 may include several dielectric layers (e.g., a silicon nitride layer and a silicon dioxide layer, not shown), the passivation trench 152 may be formed in one or multiple (up to all) dielectric layers. For a non-limiting example, the passivation trench 152 may be formed due to the local thickness reduction in the silicon dioxide layer, while the silicon nitride layer continuously/conformally extends over exposed surfaces of the silicon dioxide layer. Similarly, the passivation ridge 154 may be formed in one or multiple (up to all) dielectric layers. For a non-limiting example, the passivation ridge 154 may be formed due to the local thickness increase in the silicon dioxide layer, while the silicon nitride layer continuously/conformally extends over exposed surfaces of the silicon dioxide layer.

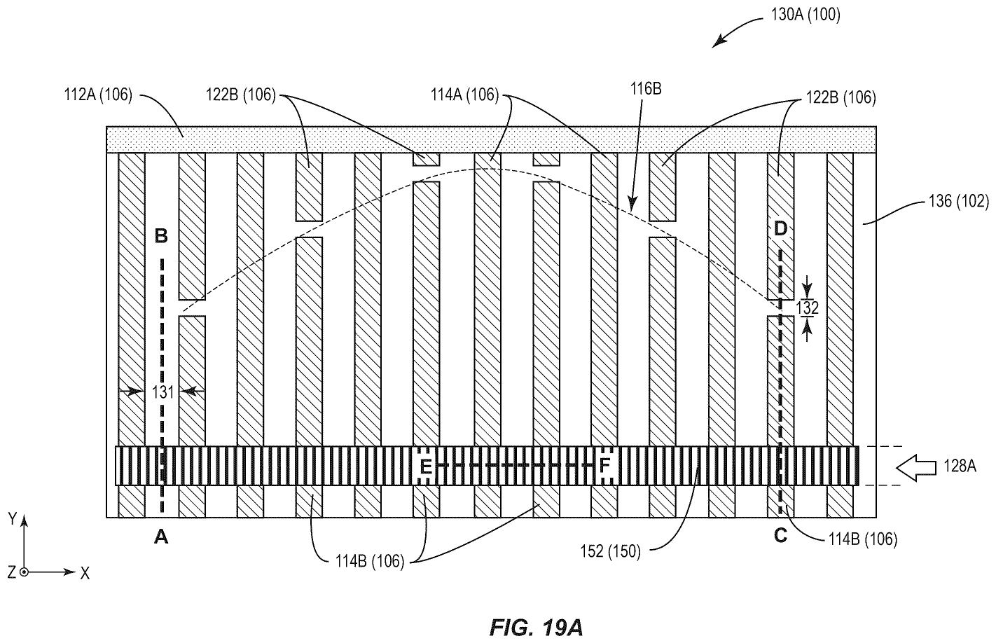

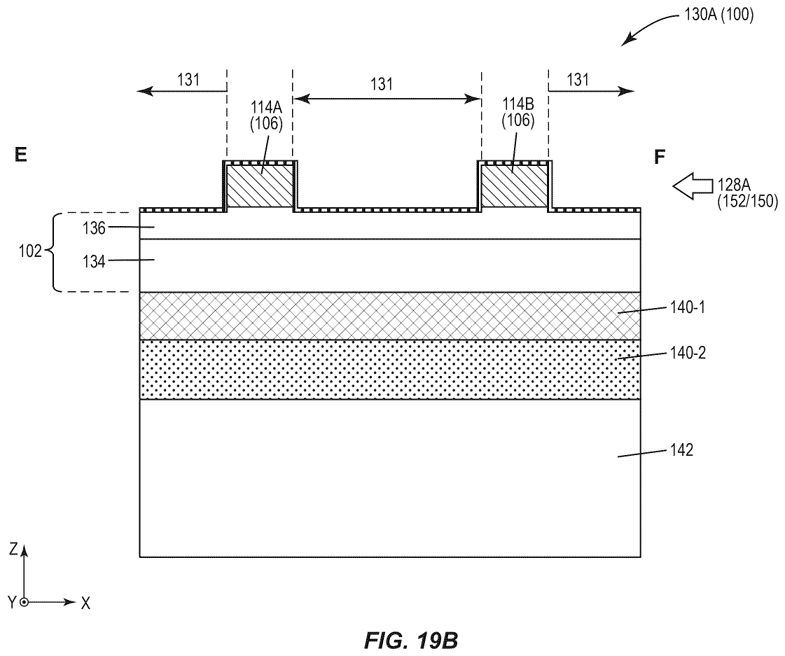

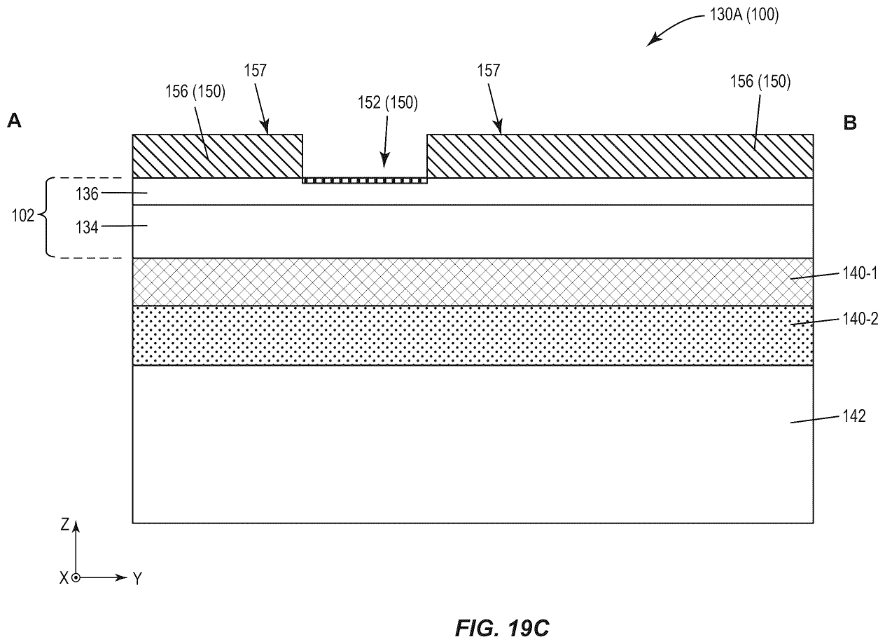

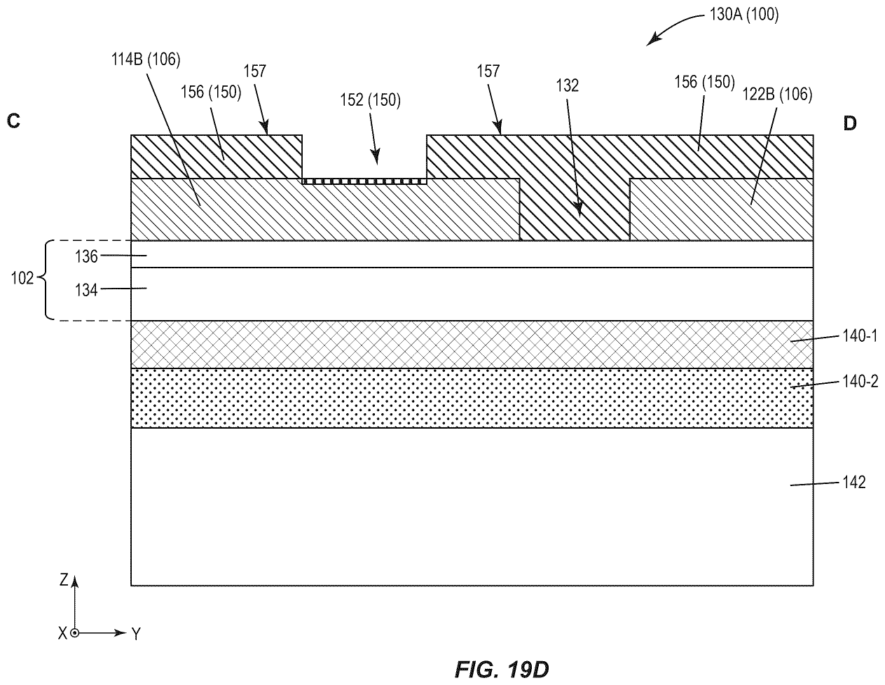

FIGS. 19A-24C illustrate different configurations for achieving fast/slow regions in a transverse direction by locally changing a thickness of the passivation structure 150. FIGS. 19A-19D illustrate enlarged views of the first edge portion 130A of the SAW resonator 100 with the first edge region 128A in FIG. 2 according to some embodiments. FIG. 19A is a top view of the first edge portion 130A, where the passivation base 156 of the passivation structure 150 is omitted for clarity. FIGS. 19B-19D are different cross-sectional views of the first edge portion 130A, where FIG. 19B is a cross-sectional view along the E-F dashed line in a resonator's propagation direction (i.e., in the x direction), FIG. 19C is a cross-sectional view along the A-B dashed line (in the y direction) through the electrode width gap 131, and FIG. 19D is a cross-sectional view along the C-D dashed line on the electrode finger 114 and its corresponding dummy electrode 122 (in the y direction). For clarity, only certain dummy electrodes and certain electrode fingers are labeled with reference numbers.

Herein, the first edge region 128A is realized in the IDT 106 by the thickness variation within the passivation structure 150 to achieve regions of different velocities in the transverse direction (i.e., the y direction). The passivation structure 150 includes the passivation base 156 and one continuous passivation trench 152 formed in the passivation base 156. For the purpose of this illustration, the piezoelectric structure 102 may have a uniform thickness and does not contribute to thickness variation/resonance velocity changes in the transverse direction. The passivation base 156 may substantially cover an entire top surface of the SAW resonator 100 (e.g., substantially covers the IDT 106 and the exposed surfaces of the piezoelectric structure 102, see FIGS. 19C and 19D) and provides the planarized top surface 157 (the passivation base 156 fills each electrode width gap 131 between adjacent electrode fingers 114A/114B and each transverse gap 132 between one electrode finger 114 and its corresponding dummy electrode 122). In the transverse direction (in the y direction), the passivation trench 152 continuously extends over certain electrode fingers 114A/114B and the electrode width gaps 131 among these electrode fingers 114A/114B. In the z direction, the passivation trench 152 extends through the passivation base 156 (i.e., the relative dielectric trench depth t_{DT,rel}=100%) from the flat top surface of the passivation base 156 to a bottom side of the passivation base 156. The passivation trench 152 may have a rectangular shape in the y-z dimensions. In different applications, there might be more than one passivation trench 152 formed in the passivation base 156 with different depths and/or different shapes. By utilizing the passivation trench 152 in the passivation base 156, the passivation structure 150 achieves a thickness variation, and the first edge region 128A herein may achieve a slower region than other regions confined in the IDT 106.

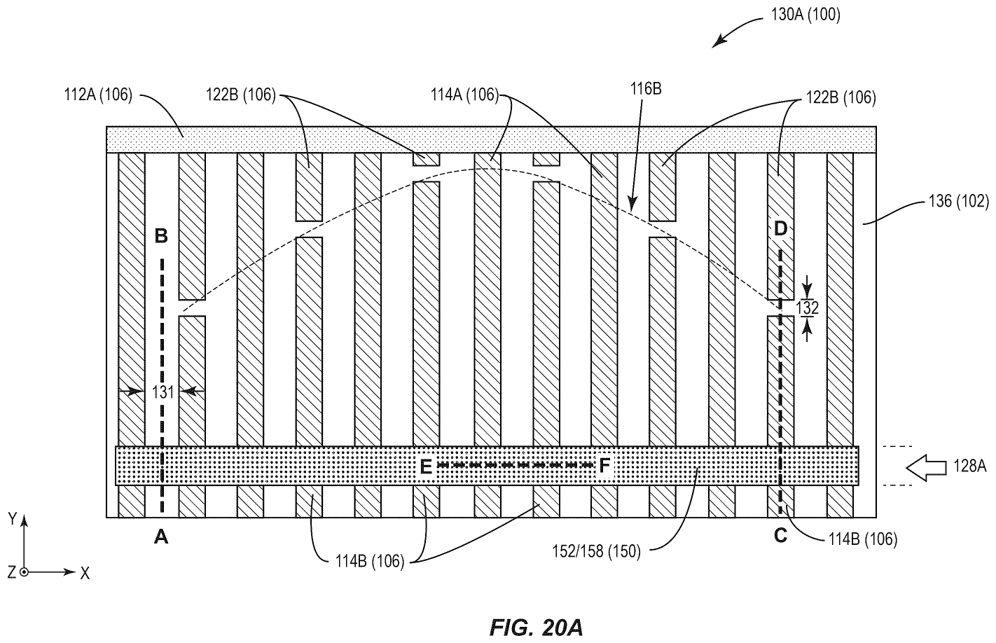

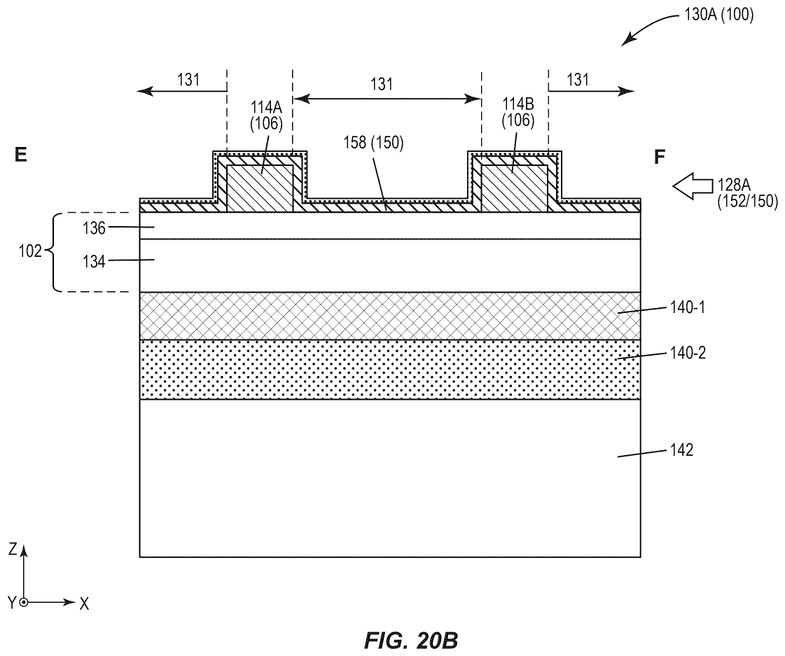

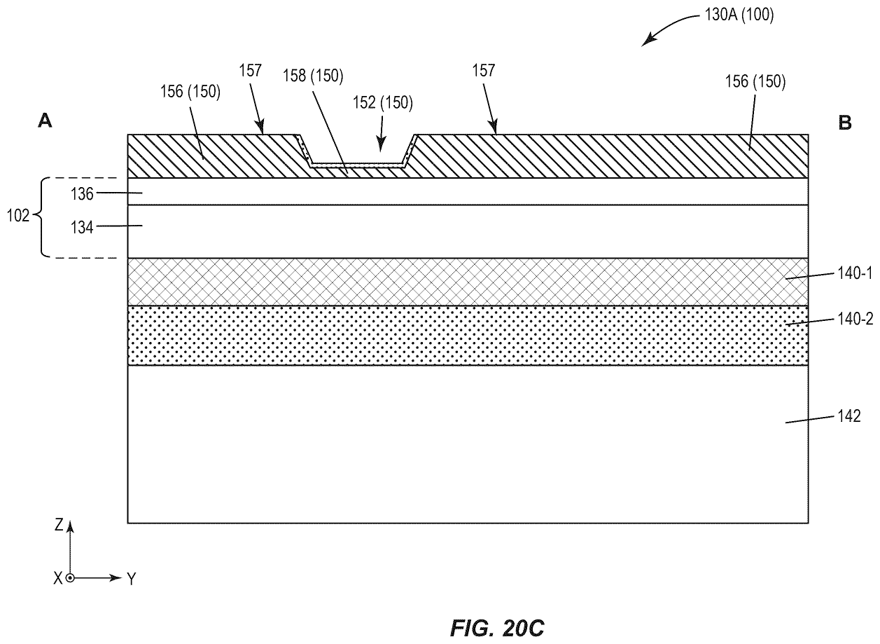

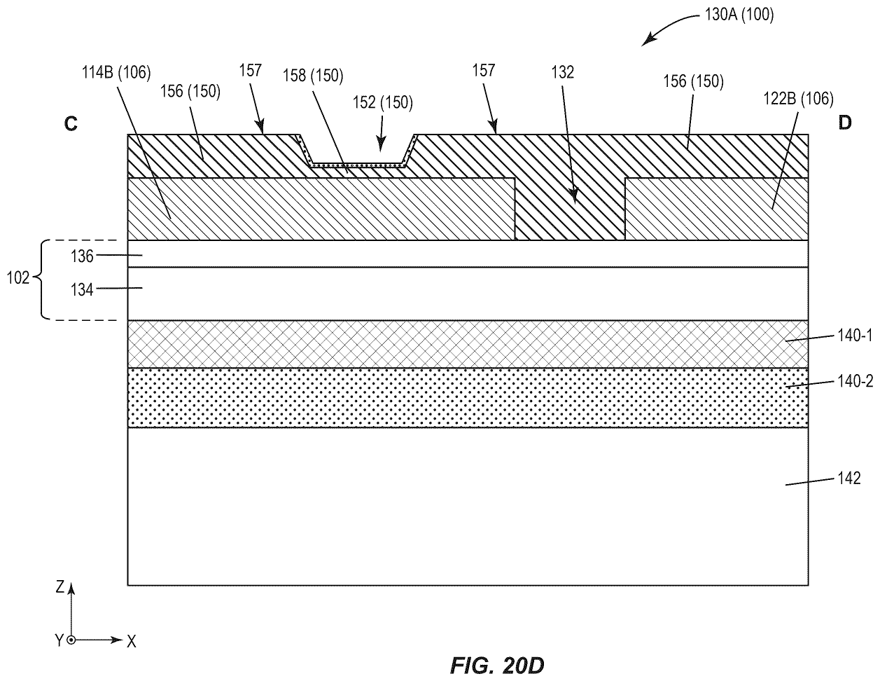

In some embodiments, the passivation trench 152 may not extend completely through the passivation base 156 in the z direction, as illustrated in FIGS. 20A-20D. FIG. 20A is a top view of the first edge portion 130A, where the passivation base 156 of the passivation structure 150 is omitted for clarity. FIGS. 20B-20D still illustrate different cross-sectional views of the first edge portion 130A. For clarity, only certain dummy electrodes and certain electrode fingers are labeled with reference numbers. Herein, the pattern shading over the passivation trench 152 is used solely to indicate locations of the non-penetrating passivation trench 152 and does not represent any additional material.

For the purpose of this illustration, the piezoelectric structure 102 may have a uniform thickness and does not contribute to thickness variation/resonance velocity changes in the transverse direction. The passivation base 156 substantially covers an entire top surface of the SAW resonator 100 (e.g., substantially covers the IDT 106 and exposed surfaces of the piezoelectric structure 102, see FIGS. 20C and 20D) and provides the planarized top surface 157 (the passivation base 156 fills each electrode width gap 131 and each transverse gap 132). Herein and hereafter, substantially covering one surface refers to covering the surface by at least 60%, and preferably over 85%. In the transverse direction (in the y direction), the passivation trench 152 still continuously extends over certain electrode fingers 114A/114B and the electrode width gaps 131 among these electrode fingers 114A/114B. In the z direction, the passivation trench 152 extends from the top surface of the passivation base 156 toward the bottom side of the passivation base 156 without extending through the passivation base 156 (i.e., the relative dielectric trench depth t_{DT,rel}<100%) in the z direction. There is a passivation residue 158 directly underneath the passivation trench 152 and directly connected to the passivation base 156. The passivation residue 158 may have a uniform or variable thickness, and the passivation trench 152 may have a uniform or variable depth. The passivation trench 152 may have an approximately trapezoidal shape in the y-z dimensions. By utilizing the passivation trench 152 in the passivation base 156, the passivation structure 150 achieves a thickness variation, and the first edge region 128A herein may achieve a slower region than other regions confined in the IDT 106.

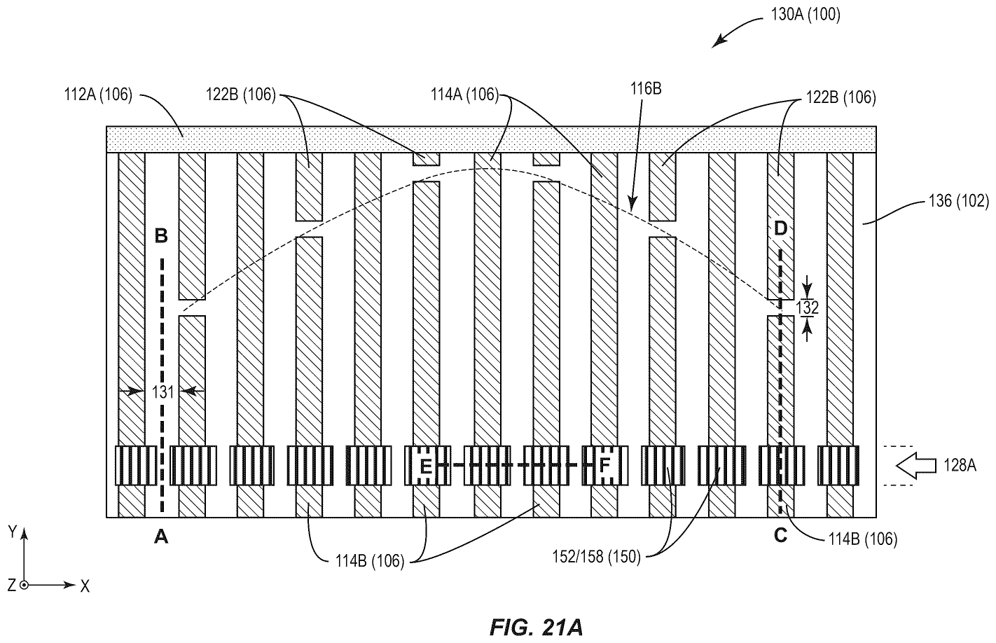

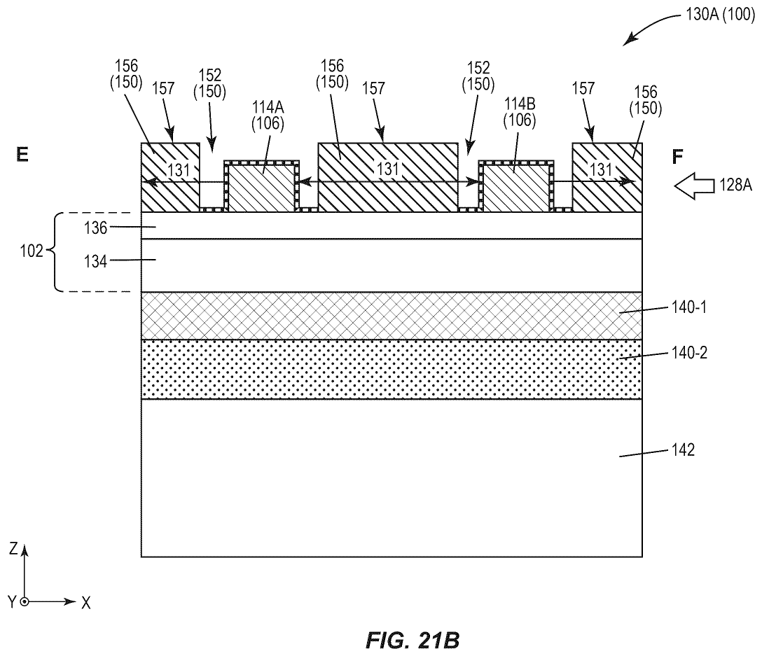

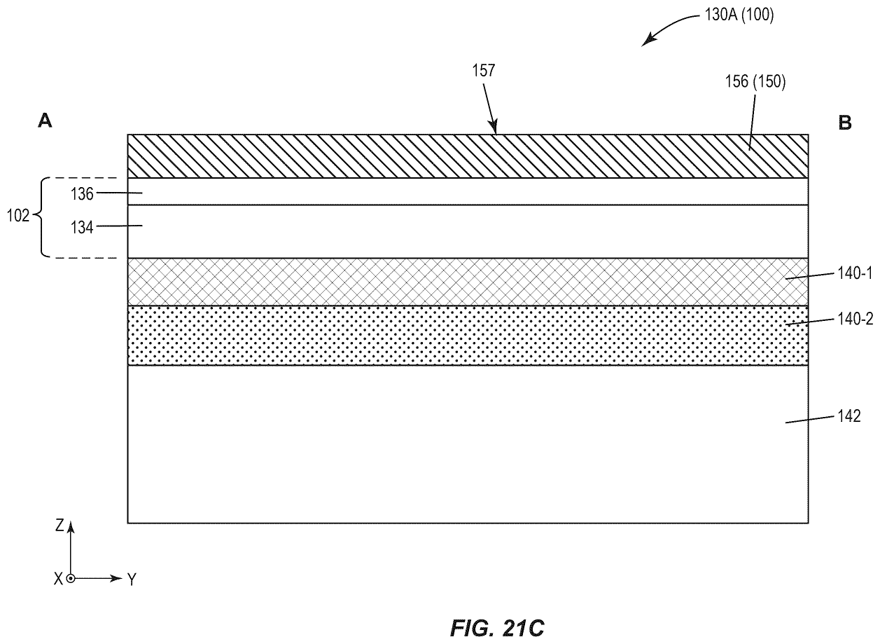

In some embodiments, there are multiple discrete passivation trenches 152 formed in the passivation base 156, as illustrated in FIGS. 21A-21C. Herein, FIG. 21A is a top view of the first edge portion 130A, where the passivation base 156 of the passivation structure 150 is omitted for clarity. FIGS. 21B-21C illustrate different cross-sectional views of the first edge portion 130A (a cross-sectional view along the C-D dashed line is similar to the illustration shown in FIG. 19D). For clarity, only certain dummy electrodes and certain electrode fingers are labeled with reference numbers.

Herein, the first edge region 128A is still realized in the IDT 106 by the thickness variation within the passivation structure 150 to achieve regions of different velocities in the transverse direction (i.e., the y direction). For the purpose of this illustration, the piezoelectric structure 102 may have a uniform thickness and does not contribute to thickness variation/resonance velocity changes in the transverse direction. The passivation base 156 substantially covers an entire top surface of the SAW resonator 100 (e.g., substantially covers the IDT 106 and exposed surfaces of the piezoelectric structure 102, see FIGS. 21B and 21C) and provides the planarized top surface 157 (the passivation base 156 fills each electrode width gap 131 and each transverse gap 132). Each discrete passivation trench 152 is located about a corresponding one of certain electrode fingers 114A/114B (shown in FIG. 21B). A portion of each of the certain electrode fingers 114A/114B is not covered by the passivation base 156, while the passivation base 156 substantially covers the electrode width gaps 131 among the certain electrode fingers 114A/114B (shown in FIGS. 21B and 21C). Each passivation trench 152 may have a rectangular shape in the x-y dimensions, and no passivation residue 158 exists underneath each passivation trench 152. In addition, the passivation trenches 152 may be aligned in the x direction (e.g., no shift in the y direction, shown in FIG. 21A). In different applications, each passivation trench 152 may have any proper shape in the x-y/x-z/y-z dimensions, such as a circular shape, an oval shape, a parabolic shape, a rounded shape, a square shape, a rectangular shape, a parallelogram shape, a trapezoidal shape or a polygonal shape. The passivation trenches 152 may have a shift in the x/y direction and the passivation residue 158 might be present underneath one or more passivation trenches 152. By utilizing these multiple passivation trenches 152 in the passivation base 156, the passivation structure 150 achieves a thickness variation, and the first edge region 128A herein may achieve a slower region than other regions confined in the IDT 106.

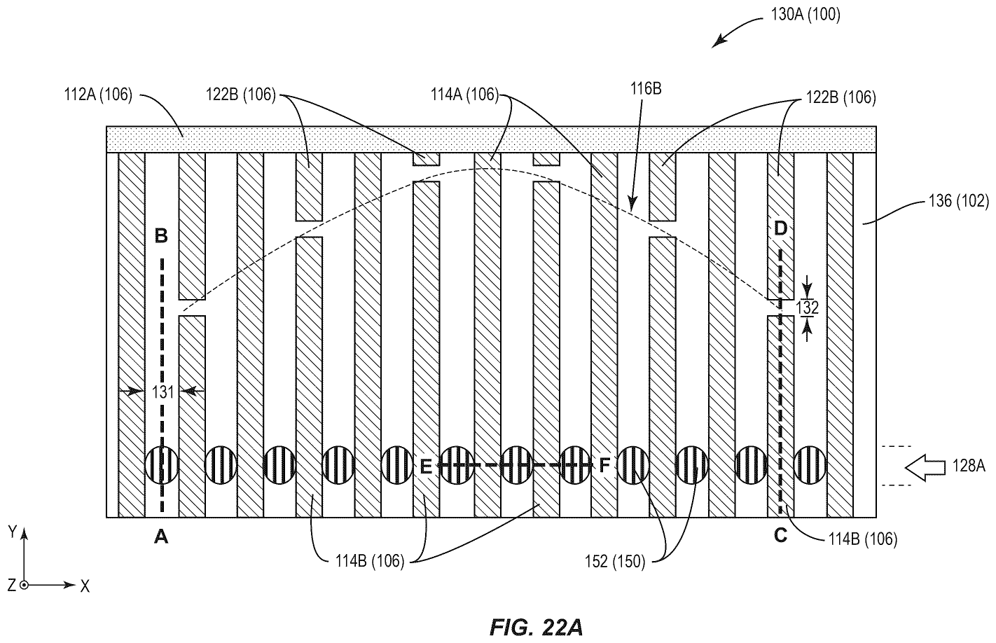

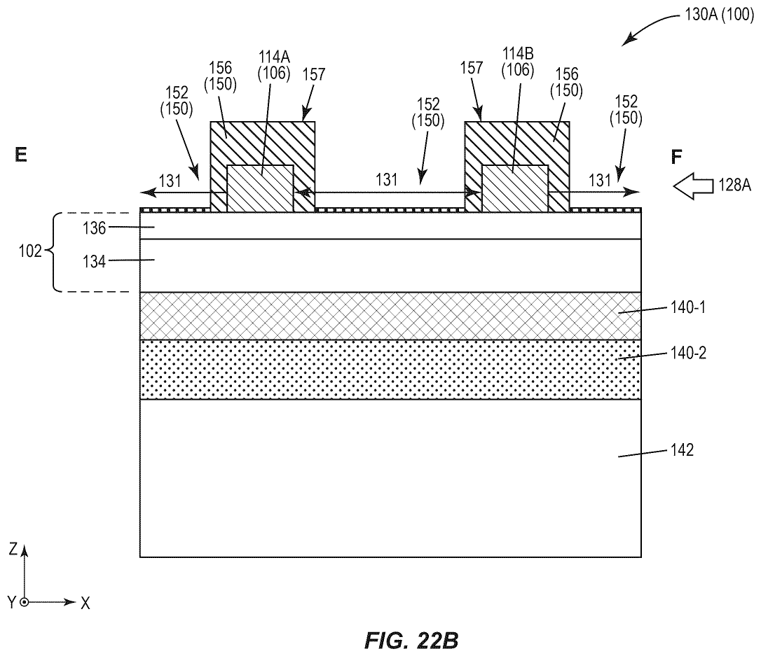

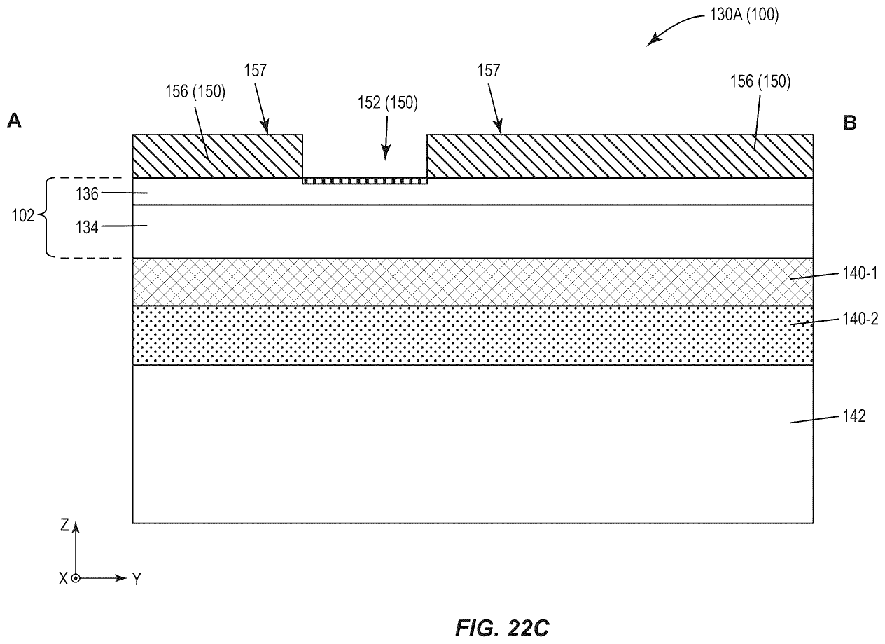

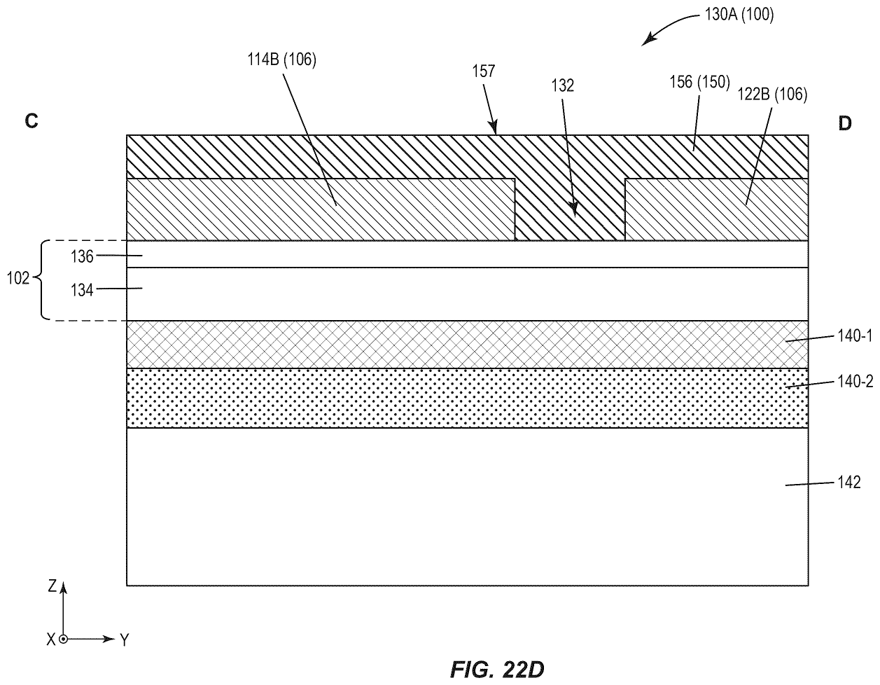

In some embodiments, there are multiple discrete passivation trenches 152 formed in the passivation base 156, where each passivation trench 152 is located in a corresponding electrode width gap 131 between one first electrode finger 114A and an adjacent second electrode finger 114B without overlapping with any electrode finger 114, as illustrated in FIGS. 22A-22D. In other words, each electrode finger 114 is covered by the passivation base 156. Herein, FIG. 22A is a top view of the first edge portion 130A, where the passivation base 156 of the passivation structure 150 is omitted for clarity. FIGS. 22B-22D illustrate different cross-sectional views of the first edge portion 130A. For clarity, only certain dummy electrodes and certain electrode fingers are labeled with reference numbers.

For the purpose of this illustration, the piezoelectric structure 102 may have a uniform thickness and does not contribute to thickness variation/resonance velocity changes in the transverse direction. The passivation base 156 substantially covers an entire top surface of the SAW resonator 100 (e.g., substantially covers the IDT 106 and exposed surfaces of the piezoelectric structure 102, see FIGS. 22B-22D) and provides the planarized top surface 157 (the passivation base 156 fills each electrode width gap 131 and each transverse gap 132). Each passivation trench 152 may have an oval shape in the x-y dimensions and a rectangular shape in the y-z/x-z dimensions, and extends vertically through the passivation base 156 (i.e., the relative dielectric trench depth t_{DT,rel}=100%) in the z direction. In addition, the passivation trenches 152 may be aligned in the x direction (e.g., no shift in the y direction, shown in FIG. 22A). In different applications, each passivation trench 152 may have any proper shape in the x-y/x-z/y-z dimensions, such as a circular shape, an oval shape, a parabolic shape, a rounded shape, a square shape, a rectangular shape, a parallelogram shape, a trapezoidal shape or a polygonal shape. The passivation trenches 152 may have a shift in the y direction and the passivation residue 158 might be present underneath one or more passivation trenches 152. By utilizing these multiple passivation trenches 152 in the passivation base 156, the passivation structure 150 achieves a thickness variation, and the first edge region 128A herein may achieve a slower region than other regions confined in the IDT 106.

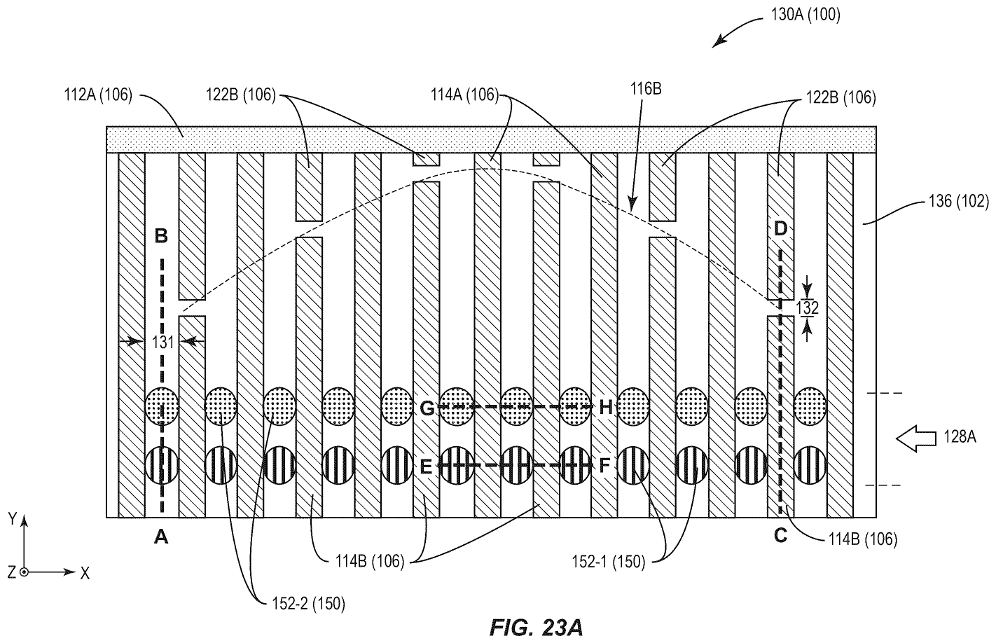

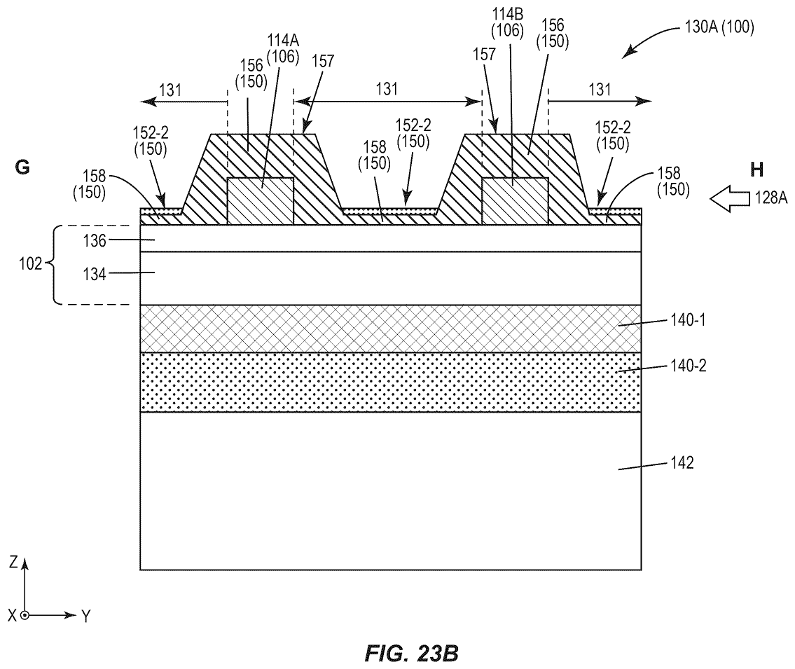

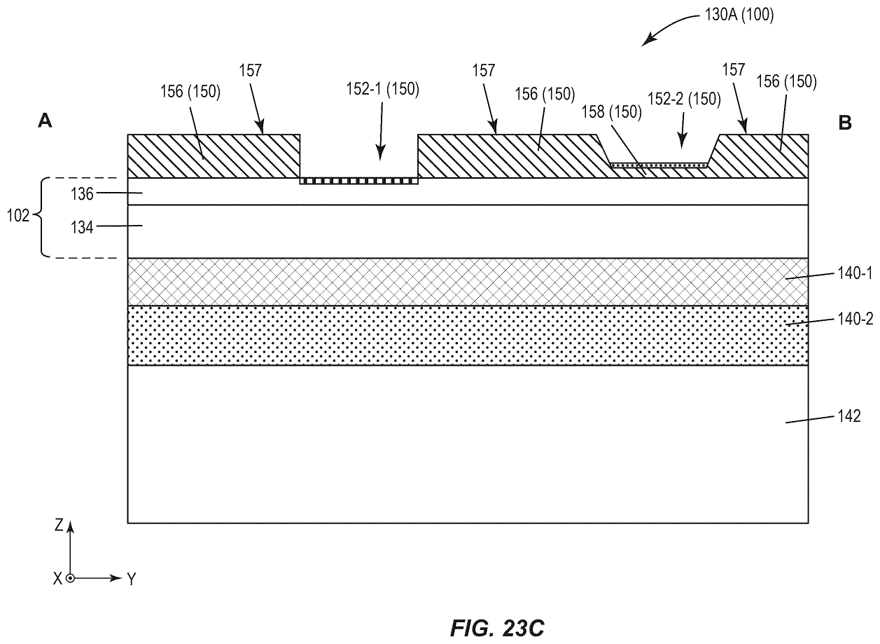

In some embodiments, there might be more than one passivation trench 152 along the y-direction, as illustrated in FIGS. 23A-23C. Herein, FIG. 23A is a top view of the first edge portion 130A, where the passivation base 156 of the passivation structure 150 is omitted for clarity. FIG. 23B is a cross-sectional view along the G-H dashed line in a resonator's propagation direction (i.e., in the x direction), and FIG. 23C is a cross-sectional view along the A-B dashed line (in the y direction) through the electrode width gap 131. A cross-sectional view along the E-F dashed line is similar to the illustration shown in FIG. 22B, and a cross-sectional view along the C-D dashed line is similar to the illustration shown in FIG. 22D. For clarity, only certain dummy electrodes and certain electrode fingers are labeled with reference numbers.

For the purpose of this illustration, the passivation trenches 152 include multiple discrete first passivation trenches 152-1 and multiple discrete second passivation trenches 152-2. Herein and hereafter, the pattern shading over the first passivation trenches 152-1 is used solely to clearly indicate locations of the first passivation trenches 152-1 and does not represent any additional material. Similarly, the pattern shading over the second passivation trenches 152-2 is used solely to clearly indicate locations of the second passivation trenches 152-2 and does not represent any additional material. Each first passivation trench 152-1 and a corresponding second passivation trench 152-2 are aligned in the y direction and located in the corresponding electrode width gap 131 between one first electrode finger 114A and an adjacent second electrode finger 114B in the x direction without overlapping with any electrode finger 114. Each electrode finger 114 is still covered by the passivation base 156.

Each first passivation trench 152-1 may have an oval shape in the x-y dimensions and a rectangular shape in the y-z/x-z dimensions, and extends through the passivation base 156 (i.e., the relative dielectric trench depth t_{DT,rel}=100%) in the z direction. Each second passivation trench 152-2 may have an oval shape in the x-y dimensions and a trapezoidal shape in the y-z/x-z dimensions, and extends from the top surface of the passivation base 156 toward the bottom surface of the passivation base 156 without extending through the passivation base 156 (i.e., the relative dielectric trench depth t_{DT,rel}<100%) in the z direction. There is one passivation residue 158 directly underneath each second passivation trench 152-2 and directly connected to the passivation base 156. The passivation residue 158 may have a uniform thickness, and the second passivation trench 152-2 may have a uniform depth. In addition, the first passivation trenches 152-1 may be aligned in the x direction (e.g., no shift in the y direction, shown in FIG. 23A), and the second passivation trenches 152-2 may be aligned in the x direction (e.g., no shift in the y direction, shown in FIG. 23A). In different applications, each first passivation trench 152-1/second passivation trench 152-2 may have any proper shape in the x-y/x-z/y-z dimensions, such as a circular shape, an oval shape, a parabolic shape, a rounded shape, a square shape, a rectangular shape, a parallelogram shape, a trapezoidal shape or a polygonal shape. The first passivation trenches 152-1 and the second passivation trenches 152-2 may have a same or different size (in depth, width, length) and/or shape. The first passivation trenches 152-1 and/or the second passivation trenches 152-2 may have a shift in the y direction and/or in the x direction. By utilizing these first and second passivation trenches 152-1 and 152-2 in the passivation base 156, the passivation structure 150 achieves a thickness variation, and the first edge region 128A herein achieves a slower region than other regions confined in the IDT 106.

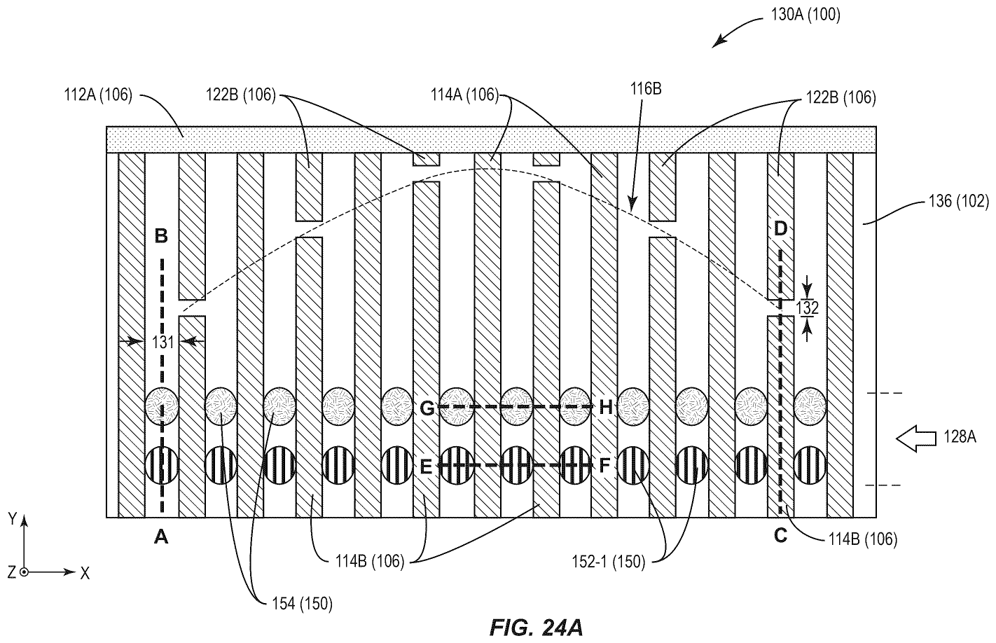

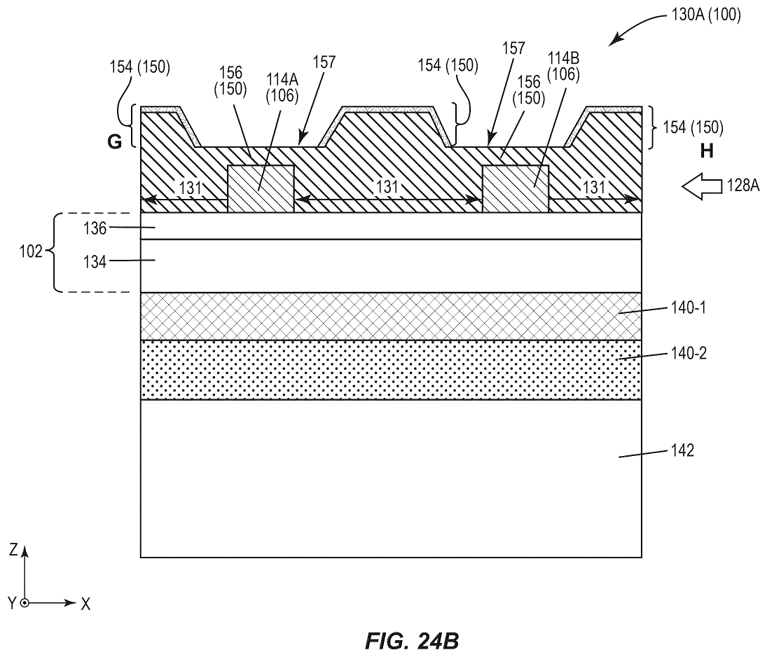

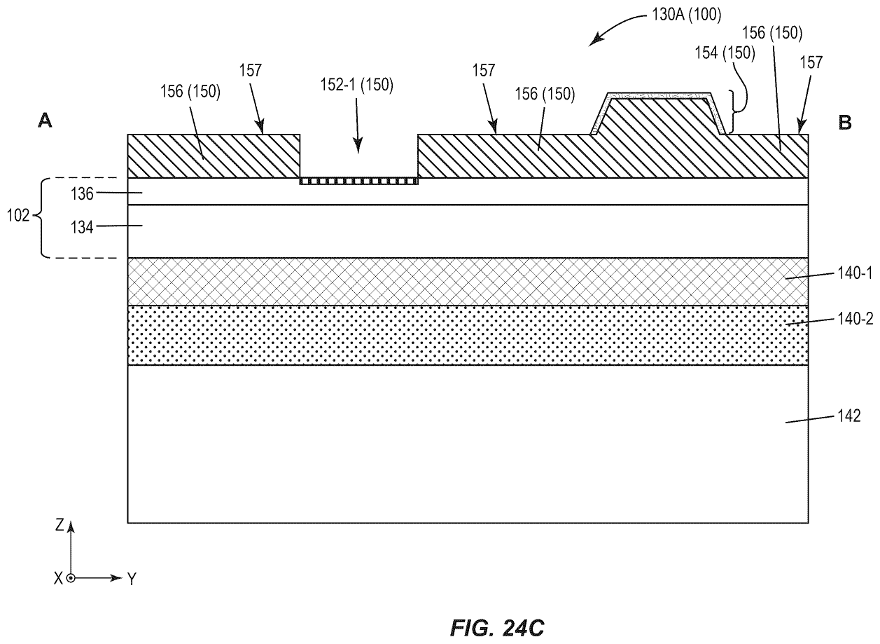

In some embodiments, the passivation structure 150 includes both passivation trenches 152 formed in the passivation base 156 and one or more passivation ridges 154 formed over the passivation base 156, as illustrated in FIGS. 24A-24C. Herein, FIG. 24A is a top view of the first edge portion 130A, where the passivation base 156 of the passivation structure 150 is omitted for clarity. FIG. 24B is a cross-sectional view along the G-H dashed line in a resonator's propagation direction (i.e., in the x direction), and FIG. 23C is a cross-sectional view along the A-B dashed line (in the y direction) through the electrode width gap 131. A cross-sectional view along the E-F dashed line is similar to the illustration shown in FIG. 22B, and a cross-sectional view along the C-D dashed line is similar to the illustration shown in FIG. 22D. For clarity, only certain dummy electrodes and certain electrode fingers are labeled with reference numbers.

For the purpose of this illustration, the passivation structure 150 includes multiple discrete passivation trenches 152 and multiple discrete passivation ridges 154. Each passivation trench 152 and a corresponding passivation ridge 154 are aligned in the y direction and located in the corresponding electrode width gap 131 without overlapping with any electrode finger 114. Each electrode finger 114 is still covered by the passivation base 156. Each passivation trench 152 may have an oval shape in the x-y dimensions and a rectangular shape in the y-z/x-z dimensions, and extends through the passivation base 156 (i.e., the relative dielectric trench depth t_{DT,rel}=100%) in the z direction. Each passivation ridge 154 may have an oval shape in the x-y dimensions and a trapezoidal shape in the y-z/x-z dimensions, and protrudes from the flat top surface 157 of the passivation base 156 in the z direction. In addition, the passivation trenches 152 may be aligned in the x direction (e.g., no shift in the y direction, shown in FIG. 24A), and the passivation ridges 154 may be aligned in the x direction (e.g., no shift in the y direction, shown in FIG. 24A). In different applications, each passivation trench 152/each passivation ridge 154 may have any proper shape in the x-y/x-z/y-z dimensions, such as a circular shape, an oval shape, a parabolic shape, a rounded shape, a square shape, a rectangular shape, a parallelogram shape, a trapezoidal shape or a polygonal shape. The passivation trenches 152 and/or the passivation ridges 154 may have a shift in the y direction and/or in the x direction. By utilizing the passivation trenches 152 and the passivation ridges 154, the passivation structure 150 achieves thickness variations, and the first edge region 128A herein may achieve both a slower region (e.g., along the passivation trenches 152) and a faster region (e.g., along the passivation ridges 154) in the transverse direction than other regions confined in the IDT 106 (e.g., covered by the passivation base 156 without the passivation trench 152 and the passivation ridge 154).

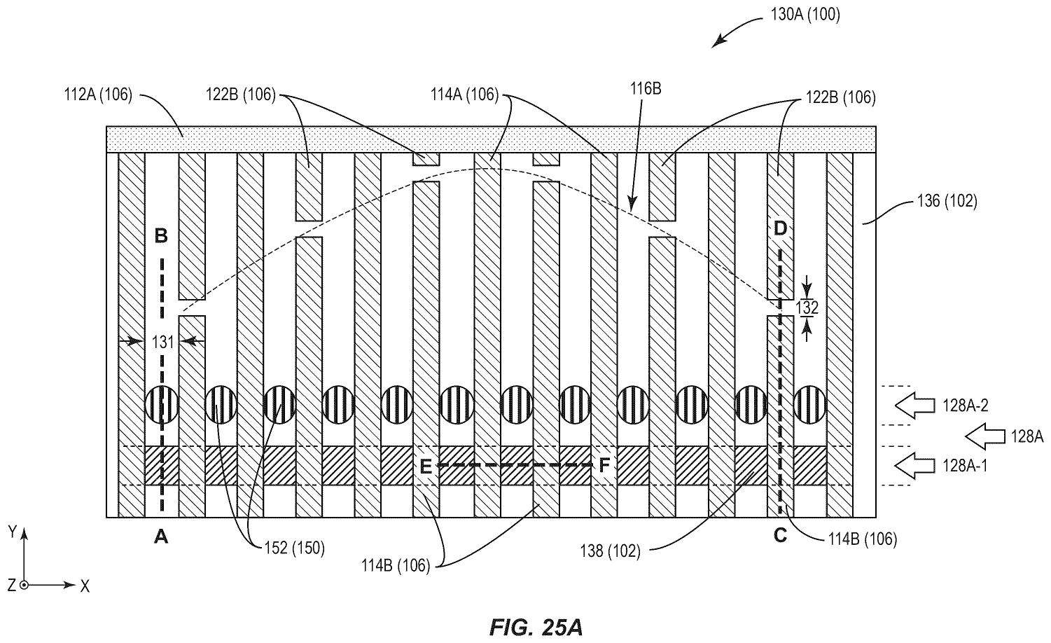

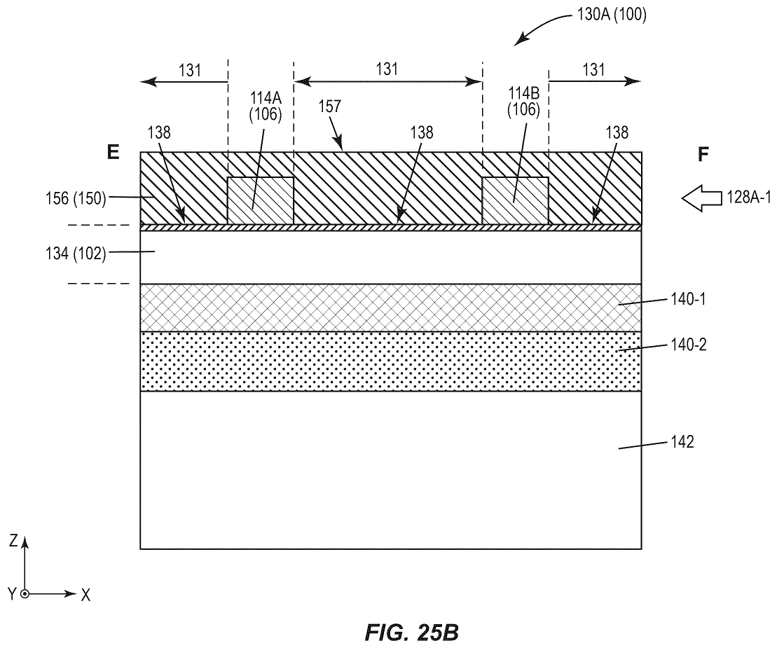

In some embodiments, the thickness variation of the passivation structure 150 can be combined with the thickness variation of the piezoelectric structure 102, which allows even more design freedom to achieve velocity contrast in a transverse direction. FIGS. 25A-25D illustrate an exemplary implementation of the first edge region 128A by utilizing the passivation trenches 152 in the passivation structure 150 and one continuous piezoelectric trench 138 in the piezoelectric structure 102 according to some embodiments. FIG. 25A is a top view of the first edge portion 130A, where the passivation base 156 of the passivation structure 150 is omitted for clarity. FIG. 25B is a cross-sectional view along the E-F dashed line in a resonator's propagation direction (similar to the illustration shown in FIG. 5B and including the passivation structure 150), FIG. 25C is a cross-sectional view along the A-B dashed line (in the y direction) through the electrode width gap 131, and FIG. 25D is a cross-sectional view along the C-D dashed line on the electrode finger 114 and its corresponding dummy electrode 122 (in the y direction). A cross-sectional view along the G-H dashed line is similar to the illustration shown in FIG. 22B. For clarity, only certain dummy electrodes and certain electrode fingers are labeled with reference numbers.

For the purpose of this illustration, the first edge region 128A includes a first sub-edge region 128A-1 and a second sub-edge region 128A-2, each of which achieves a different velocity than the other regions confined in the IDT 106. The continuous piezoelectric trench 138 and the passivation trenches 152 have no overlap in x-y dimensions. In other words, at regions where the thickness variation exists in the piezoelectric structure 102, no thickness variation exists in the passivation structure 150, and at regions where the thickness variation exists in the passivation structure 150, no thickness variation exists in the piezoelectric structure 102. Herein, the first sub-edge region 128A-1 is realized by including one continuous piezoelectric trench 138 in the piezoelectric structure 102 (along the x direction), where no thickness variation in the passivation structure 150 exists within the first sub-edge region 128A-1. The second sub-edge region 128A-2 is realized by including the multiple passivation trenches 152 in the passivation structure 150 (along the x direction), where no thickness variation in the piezoelectric structure 102 exists within the second sub-edge region 128A-2.

The piezoelectric structure 102 includes the lower piezoelectric region 134 and the upper piezoelectric region 136, where the continuous piezoelectric trench 138 is formed in the upper piezoelectric region 136. The piezoelectric trench 138 continuously extends in the x direction and at least across certain electrode fingers 114A/114B and the electrode width gaps 131 among these electrode fingers 114A/114B. A portion of each of these certain electrode fingers 114A/114B extends over the piezoelectric trench 138 in the y direction. The thickness of the piezoelectric structure 102 within the piezoelectric trench 138 (i.e., only the thickness of the lower piezoelectric region 134) is thinner than a thickness of any remaining portions of the piezoelectric structure 102 (i.e., a combination thickness of the thickness of the lower piezoelectric region 134 and the thickness of the upper piezoelectric region 136). The passivation base 156 substantially covers an entire top surface of the SAW resonator 100 (e.g., substantially covering the IDT 106 and exposed surfaces of the piezoelectric structure 102, see FIGS. 25B-25D) and provides the planarized top surface 157 (the passivation base 156 fills each electrode width gap 131 and each transverse gap 132). Each passivation trench 152 may have an oval shape in the x-y dimensions and a rectangular shape in the y-z/x-z dimensions, and extends through the passivation base 156 (i.e., the relative dielectric trench depth t_{DT,rel}=100%) in the z direction (see FIG. 25C). In addition, the passivation trenches 152 may be aligned in the x direction (e.g., no shift in the y direction, shown in FIG. 25A).

In different applications, the piezoelectric trench 138 and the passivation trenches 152 may have some overlap in x-y dimensions. The piezoelectric trench 138 and each passivation trench 152 may have any proper shape in the x-y/x-z/y-z dimensions. The piezoelectric trench 138 and the passivation trenches 152 may be positioned at different locations confined in the IDT 106.

To achieve velocity contrast regions transversely across the IDT 106 and thereby suppress the transverse mode of the SAW resonator 100, the piezoelectric structure 102 and the passivation structure 150 have much more design flexibility compared to geometry changes of the electrode fingers 114, and have less risks and drawbacks compared to adding metal materials to the electrode fingers 114. In some embodiments, the velocity contrast regions can be achieved solely by the thickness variations of the piezoelectric structure 102 using one or more piezoelectric trenches 138 and/or one or more piezoelectric ridges 146. The one or more piezoelectric trenches 138 and the one or more piezoelectric ridges 146 are flexible in size (e.g. depth, thickness, width, length), shape, and location. The one or more piezoelectric trenches 138 and the one or more piezoelectric ridges 146 may be used simultaneously or separately within the piezoelectric structure 102. In some embodiments, the velocity contrast regions can be achieved solely by the thickness variations of the passivation structure 150 using one or more passivation trenches 152 and/or one or more passivation ridges 154. The one or more passivation trenches 152 and the one or more passivation ridges 154 are flexible in size (e.g. depth, thickness, width, length), shape, and location. The one or more passivation trenches 152 and the one or more passivation ridges 154 may be used simultaneously or separately within the passivation structure 150. In some embodiments, the velocity contrast regions can be achieved by both the thickness variations of the piezoelectric structure 102 and the thickness variations of the passivation structure 150. Besides the design flexibility described for the piezoelectric trenches 138, the piezoelectric ridges 146, the passivation trenches 152 and the passivation ridges 154, there is also flexibility to choose any combination from the piezoelectric trenches 138, the piezoelectric ridges 146, the passivation trenches 152 and the passivation ridges 154 to achieve thickness variations. The piezoelectric trenches 138/the piezoelectric ridges 146 may not overlap with the passivation trenches 152/the passivation ridges 154 or may overlap with the passivation trenches 152/the passivation ridges 154. Furthermore, the thickness variations of the piezoelectric structure 102 and the thickness variations of the passivation structure 150 may also be combined with the geometry changes of the electrode fingers 114 to achieve the velocity variations (e.g., locally changing widths of certain electrode fingers 114). In addition to the velocity contrast regions, the apodization technique may also be applied to the IDT 106 to further suppress the transverse mode of the SAW resonator 100.

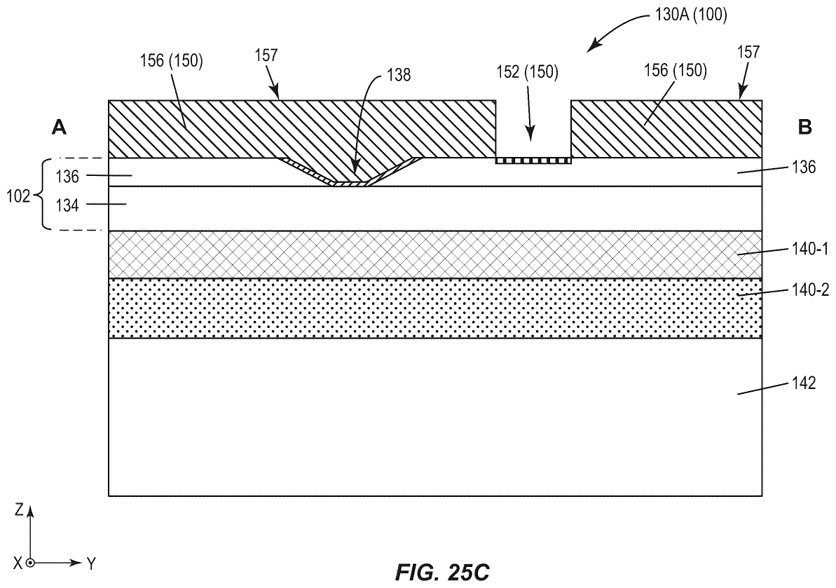

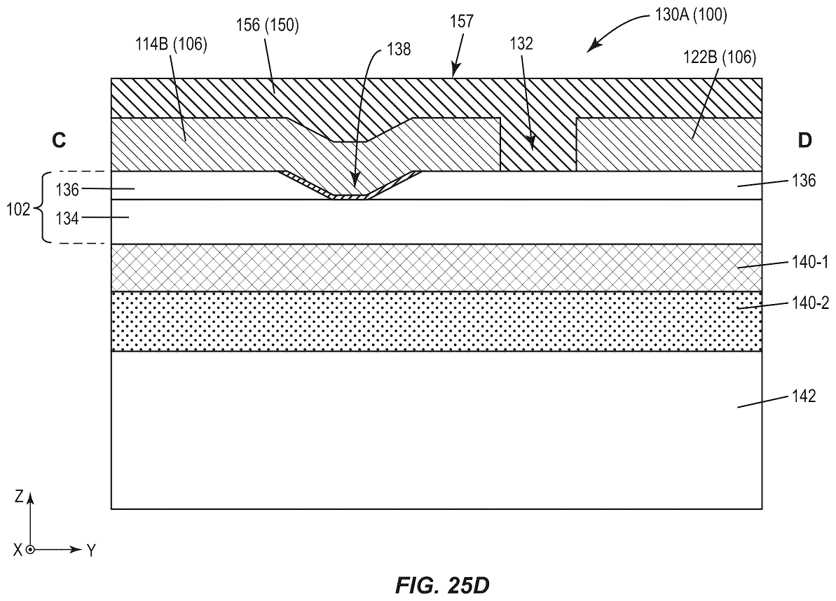

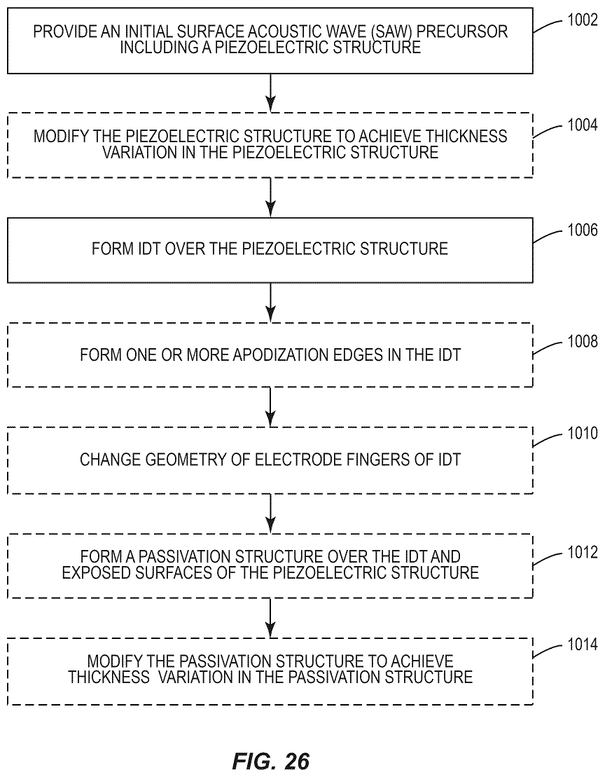

FIG. 26 illustrates a flowchart of an exemplary method of providing the SAW resonator 100 according to some embodiments of the present disclosure. Although the process steps are illustrated in a series, the process steps are not necessarily order dependent. Some steps may be taken in a different order than that presented. Further, processes within the scope of this disclosure may include fewer or more steps than those illustrated in FIG. 26. Initially, an initial SAW precursor, which at least includes a piezoelectric structure, is provided (step 1002). The piezoelectric structure within the initial SAW precursor may have a uniform thickness (e.g., the piezoelectric structure 102 shown in FIGS. 19B-19D) between 0.05 μm and 2.2 μm. In different applications, the initial SAW precursor may also include one or more dielectric layers (e.g., the one or more dielectric layers 140) underneath the piezoelectric structure, and a handle wafer (e.g., the handle wafer 142) underneath the one or more dielectric layers. Alternatively, the initial SAW precursor may include a reflection structure, which includes alternating low acoustic impedance layers and high acoustic impedance layers in the z direction, underneath the piezoelectric structure, and the handle wafer underneath the reflection structure.

Next, the piezoelectric structure may be modified to achieve a thickness variation in the piezoelectric structure (step 1004) and thereby provide the velocity contrast. The piezoelectric structure may be modified by removing piezoelectric material from the piezoelectric structure to achieve one or more piezoelectric trenches (e.g., the piezoelectric trench(es) 138) or by adding piezoelectric material to the piezoelectric structure to achieve one or more piezoelectric ridges (e.g., the piezoelectric ridge(s) 146). The piezoelectric material may be removed via chemical or physical methods, including wet etching or dry etching. Using an ion beam, e.g. an argon ion beam, is a possible method for achieving the intended removal. Areas of the piezoelectric structure that should not see material removal can selectively be covered by a resist, which may be patterned by lithography methods. In addition, the depth of each piezoelectric trench may be controlled by the removal duration, while sidewalls of each piezoelectric trench may be defined by a combination of the resist profile and the removal method details. The removal method details may include parameters such as background gases (including active chemical reactions), vacuum level and gas pressures/flow rates. For physical removal methods, an incident angle can play an important role in defining a side wall angle and the shape of each piezoelectric trench. Herein, the material removal and/or the material adding can be repeated multiple times, such that desired shapes, sizes (e.g., depth, thickness, width, length), and/or locations can be achieved and combined. In some applications, the resonance velocity contrast in the transverse direction can be achieved from the thickness variation in a passivation structure, and therefore the step of modifying the piezoelectric structure might be omitted.

Regardless of whether the piezoelectric structure is modified, an IDT (e.g., the IDT 106) is then formed over the piezoelectric structure (step 1006). Notice that the piezoelectric structure might be modified after the IDT is formed, especially the material adding and/or the material removal (e.g., the piezoelectric trenches 138 shown in FIGS. 3A, 7, 8, and 10) are provided in electrode width gaps 131 between the electrode fingers of the IDT (e.g., the electrode fingers 114A/114B) or in gaps in the transverse direction (e.g., the transverse gaps 132 or the first electrode length gaps 148A). Optionally, the IDT might be apodized (step 1008) with one or more apodization edges (e.g., the apodization edges 116A/116B), and/or geometry of certain electrode fingers of the IDT might be changed by adding/removing metal material to/from the certain electrode fingers (step 1010).

After the IDT is formed, a passivation structure might be formed over the IDT and exposed surfaces of the piezoelectric structure (step 1012). Herein, the passivation structure may have a configuration as shown in FIGS. 17A-17D. The passivation structure may include one or more dielectric layers, which may be formed of silicon dioxide, silicon nitride, silicon oxynitride, and/or titanium oxide among others. In some applications, such as when one or more piezoelectric trenches (e.g., the piezoelectric trenches 138) are utilized to realize the velocity contrast, the passivation structure might be omitted.

If the passivation structure is present, the passivation structure may be modified to achieve a thickness variation in the passivation structure (step 1014) and thereby provide the velocity contrast. The passivation structure may be modified by removing dielectric material from the passivation structure to achieve one or more passivation trenches (e.g., the passivation trench(es) 152) or by adding dielectric material to the passivation structure to achieve one or more passivation ridges (e.g., the passivation ridge(s) 154). The dielectric material may be removed via chemical or physical methods similar to those described for the piezoelectric material. In some applications, the resonance velocity contrast in the transverse direction might be achieved from the thickness variation in the piezoelectric structure, and therefore the step of modifying the passivation structure might be omitted.

As removing dielectric/piezoelectric material can also be used for frequency trimming of one resonator, locally removing dielectric/piezoelectric material as described above may further be combined with the frequency trimming scheme. In other words, material removal in most of the resonator area is used for frequency adjustment, while local material removal in one or more certain areas is used for adjusting velocity profiles. This combination may improve upon variations in transverse mode suppression during manufacturing and hence may ensure ripple-free filters in high volume production.

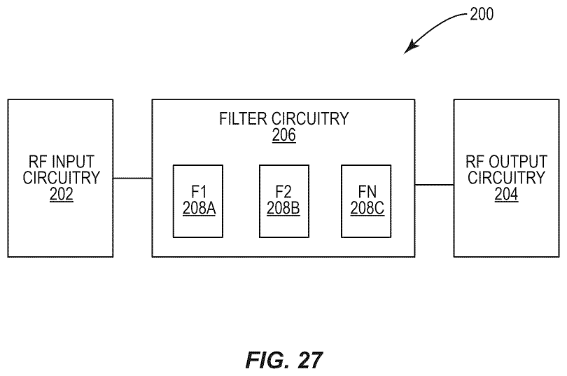

FIG. 27 illustrates a block diagram of an example system 200 that includes at least one acoustic filter, which is implemented by one or more SAW resonators 100 as shown in FIGS. 2-25D. The system 200 includes radio frequency (RF) input circuitry 202, RF output circuitry 204, and filter circuitry 206 coupled between the RF input circuitry 202 and the RF output circuitry 204. In certain embodiments, the RF input circuitry 202 includes a transceiver, while the RF output circuitry 204 includes an antenna.

For the purpose of this illustration, the filter circuitry 206 includes three filters 208A, 208B, and 208C. Herein, one or more of the filters 208A, 208B, and 208C may be acoustic filters, which are implemented by one or more SAW resonators 100. In different applications, the filter circuitry 206 may include fewer or more filters. In one embodiment, each of the filters 208A, 208B, and 208C may be a lowpass filter, a high-pass filter, a notch filter, or a bandpass filter, and the filters 208A, 208B, and 208C may be connected in a cascaded arrangement. The filter types that are included in the filter circuitry 206 may be based at least on the rejection requirements of the system 200. The RF input circuitry 202 and/or the RF output circuitry 204 may include additional or different components in other embodiments.

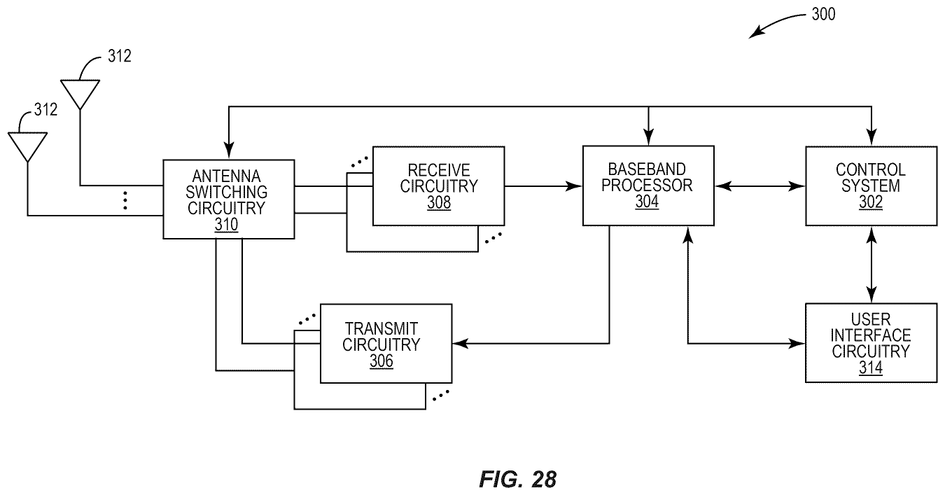

FIG. 28 illustrates a block diagram of an exemplary communication device 300, in which at least one acoustic filter implemented by one or more SAW resonators 100 as shown in FIGS. 2-25D can be provided. Herein, the communication device 300 can be any type of communication devices, such as mobile terminals, smart watches, tablets, computers, navigation devices, access points, base stations (e.g., eNB or gNB), and any other type of wireless communication devices that support wireless communications, such as cellular, wireless local area network (WLAN), Bluetooth, Ultra-wideband (UWB), and near field communications. The communication device 300 will generally include a control system 302, a baseband processor 304, transmit circuitry 306, receive circuitry 308, antenna switching circuitry 310, multiple antennas 312, and user interface circuitry 314. In a non-limiting example, the control system 302 can be a field-programmable gate array (FPGA) or an application-specific integrated circuit (ASIC), as an example. In this regard, the control system 302 can include at least a microprocessor(s), an embedded memory circuit(s), and a communication bus interface(s). The receive circuitry 308 receives radio frequency signals via the antennas 312 and through the antenna switching circuitry 310 from one or more base stations. A low noise amplifier and a filter of the receive circuitry 308 cooperate to amplify and remove broadband interference from the received signal for processing. Down conversion and digitization circuitry (not shown) will then down convert the filtered, received signal to an intermediate or baseband frequency signal, which is then digitized into one or more digital streams using an analog-to-digital converter(s) (ADC).

The baseband processor 304 processes the digitized received signal to extract the information or data bits conveyed in the received signal. This processing typically comprises demodulation, decoding, and error correction operations, as will be discussed in greater detail below. The baseband processor 304 is generally implemented in one or more digital signal processors (DSPs) and ASICs.

For transmission, the baseband processor 304 receives digitized data, which may represent voice, data, or control information, from the control system 302, which it encodes for transmission. The encoded data is output to the transmit circuitry 306, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 312 through the antenna switching circuitry 310 to the antennas 312. The multiple antennas 312 and the replicated transmit and receive circuitries 306, 308 may provide spatial diversity. Modulation and processing details will be understood by those skilled in the art. In some embodiments, the at least one acoustic filter implemented by the one or more SAW resonators 100 may be provided in any one or more of the circuitries in the communication device 300, such as the transmit circuitry 306, the receive circuitry 308, and/or the antenna switching circuitry 310.

In the previous description, resonators comprising a single IDT between reflectors are shown. As it is well known in the art, these resonators may be connected in a circuit to form a ladder filter, the resonators being used as electric elements with frequency varying impedances. It is also well known that several IDTs may be placed between the two reflectors. In this case, some of the IDTs may be connected to one electrical (input) port and the other ones to another electrical (output) port. This configuration is known as a coupled resonator filter (CRF) of a double mode SAW filter (DMS). It is also known that CRFs can be cascaded to one or several resonators to form a filter. All the embodiments above, assuming a single IDT between reflectors, can also be used without changes in the CRFs. This is not described in detail for simplicity reasons.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A surface acoustic wave (SAW) resonator, comprising:
a piezoelectric structure;
an interdigital transducer (IDT) residing over the piezoelectric structure, such that portions of the piezoelectric structure are exposed through the IDT, wherein:
the IDT comprises a plurality of first electrode fingers and a plurality of second electrode fingers extending in a transverse direction;
the plurality of first electrode fingers and the plurality of second electrode fingers are interleaved with one another along a longitudinal direction orthogonal to the transverse direction; and
the IDT has at least one edge region that extends in the longitudinal direction and spans across certain ones of the plurality of first electrode fingers and certain ones of the plurality of second electrode fingers, wherein an acoustic wave propagates in the at least one edge region at a different velocity than other regions confined in the IDT; and
a passivation structure at least partially covering the IDT and the exposed surfaces of the piezoelectric structure, wherein the at least one edge region is realized in the IDT by at least one thickness variation of a thickness variation of the piezoelectric structure and a thickness variation of the passivation structure.

2. The SAW resonator of claim 1, wherein the at least one edge region is realized in the IDT at least by the thickness variation of the piezoelectric structure.

3. The SAW resonator of claim 2, wherein:
the piezoelectric structure includes a lower piezoelectric region and an upper piezoelectric region over the lower piezoelectric region; and
the upper piezoelectric region includes at least one piezoelectric trench, which extends vertically through the upper piezoelectric region from a top surface of the upper piezoelectric region to a bottom surface of the upper piezoelectric region and is located within the at least one edge region of the IDT.

4. The SAW resonator of claim 3, wherein:
the piezoelectric structure further includes at least one piezoelectric ridge protruding upwardly from the top surface of the upper piezoelectric region; and
the at least one piezoelectric ridge is located within the at least one edge region of the IDT.

5. The SAW resonator of claim 3, wherein the at least one piezoelectric trench comprises a plurality of discrete piezoelectric trenches.

6. The SAW resonator of claim 5, wherein each of the plurality of discrete piezoelectric trenches is located between one of the plurality of first electrode fingers and an adjacent one of the plurality of second electrode fingers.

7. The SAW resonator of claim 5, wherein each of the plurality of discrete piezoelectric trenches is located underneath at least one electrode finger of both the plurality of first electrode fingers and the plurality of second electrode fingers.

8. The SAW resonator of claim 3, wherein the at least one piezoelectric trench comprises a piezoelectric trench that extends in the longitudinal direction, below at least one electrode finger of both the plurality of first electrode fingers and the plurality of second electrode fingers, and below an electrode width gap adjacent to the at least one electrode finger.

9. The SAW resonator of claim 2, wherein:
the piezoelectric structure includes a lower piezoelectric region, an upper piezoelectric region over the lower piezoelectric region, and at least one piezoelectric ridge protruding from a top surface of the upper piezoelectric region; and
the at least one piezoelectric ridge is located within the at least one edge region of the IDT.

10. The SAW resonator of claim 9, wherein the at least one piezoelectric ridge comprises a plurality of discrete piezoelectric ridges.

11. The SAW resonator of claim 10, wherein each of the plurality of discrete piezoelectric ridges is located between one of the plurality of first electrode fingers and an adjacent one of the plurality of second electrode fingers.

12. The SAW resonator of claim 10, wherein each of the plurality of discrete piezoelectric ridges is located underneath at least one electrode finger of both the plurality of first electrode fingers and the plurality of second electrode fingers.

13. The SAW resonator of claim 9, wherein the at least one piezoelectric ridge comprises a piezoelectric ridge that extends in the longitudinal direction, below at least one electrode finger of both the plurality of first electrode fingers and the plurality of second electrode fingers, and below an electrode width gap adjacent to the at least one electrode finger.

14. The SAW resonator of claim 1, wherein the edge region is realized in the IDT at least by the thickness variation of the passivation structure.

15. The SAW resonator of claim 14, wherein:
the passivation structure includes a passivation base, which provides a planarized top surface and at least one passivation trench extending vertically from the planarized top surface of the passivation base towards a bottom side of the passivation base; and
the at least one passivation trench is located within the at least one edge region of the IDT.

16. The SAW resonator of claim 15, wherein:
the passivation structure further includes at least one passivation ridge protruding upwardly from the planarized top surface of the passivation base; and
the at least one passivation ridge is located within the at least one edge region of the IDT.

17. The SAW resonator of claim 15, wherein the at least one passivation trench extends vertically through the passivation base.

18. The SAW resonator of claim 15, wherein the at least one passivation trench extends from the planarized top surface of the passivation base towards a bottom side of the passivation base without extending through the passivation base, such that a passivation residue is underneath the at least one passivation trench.

19. The SAW resonator of claim 15, wherein the at least one passivation trench comprises a plurality of discrete passivation trenches.

20. The SAW resonator of claim 14, wherein:
the passivation structure includes a passivation base, which provides a planarized top surface, and at least one passivation ridge protruding from the planarized top surface of the passivation base; and
the at least one passivation ridge is located within the at least one edge region of the IDT.

21. The SAW resonator of claim 1, wherein the edge region is realized in the IDT by the thickness variations of both the piezoelectric structure and the passivation structure.

22. The SAW resonator of claim 1, wherein at least one group of the plurality of first electrode fingers and the plurality of second electrode fingers is apodized with an apodization edge, which is defined by finger ends of the plurality of first electrode fingers and/or finger ends of the plurality of second electrode fingers.

23. The SAW resonator of claim 22, wherein:
the plurality of first electrode fingers is apodized with a first apodization edge and the plurality of second electrode fingers is apodized with a second apodization edge;
the at least one edge region of the IDT includes a first edge region located next to the second apodization edge and a second edge region located next to the first apodization edge; and
the first edge region and the second edge region are confined between the first apodization edge and the second apodization edge.

24. The SAW resonator of claim 22, wherein:
the apodization edge has a periodic pattern; and
a period of the periodic pattern is between 2 and 50 lambdas, wherein a value of one lambda is a center frequency wavelength of the SAW resonator.
